(19) United States
(12) Patent Application Publication
(10) Pub. No.: US 2026/0314197 A1
(43) Pub. Date: Oct. 8, 2026

(54) DISPLAY DEVICE AND ELECTRONIC DEVICE INCLUDING THE SAME

(71) Applicant: Samsung Display Co., Ltd., Yongin-si (KR)

(72) Inventors: YONGHEE LEE, Yongin-si (KR); JINSEON KWAK, Yongin-si (KR); KYUNG-BAE KIM, Yongin-si (KR); DONGWOO KIM, Yongin-si (KR)

(21) Appl. No.: 19/457,375

(22) Filed: Jan. 23, 2026

(30) Foreign Application Priority Data
Apr. 8, 2025 (KR) 10-2025-0045557

(51) Int. Cl. H10K 59/131; H10K 59/121

(52) U.S. Cl. CPC H10K 59/131; H10K 59/1216

(57) ABSTRACT

A display device may include a substate including an active portion, a driving transistor including the active portion and a gate electrode above the substrate and overlapping a channel region of the active portion in plan view, a capacitor including capacitor electrodes sequentially arranged above the gate electrode in a direction away from the substrate, a data line above the capacitor electrodes and configured to receive a data voltage, a direct current voltage line between the capacitor electrodes and the data line, configured to receive a direct current voltage, and overlapping the data line in plan view, and a light-emitting layer above the data line.

### CROSS-REFERENCE TO RELATED APPLICATION

The present application claims priority to and the benefit of Korean Patent Application No. 10-2025-0045557, filed on Apr. 8, 2025, in the Korean Intellectual Property Office, the entire disclosure of which is incorporated herein by reference.

### BACKGROUND

### 1. Field

Aspects of one or more embodiments may provide generally to a display device and an electronic device including the display device. For example, one or more embodiments relate to the display device which may provide visual information and the electronic device including the display device.

### 2. Description of the Related Art

As information technology develops, the importance of display devices, which are communication media between users and information, is drawing attention. Accordingly, the utilization of the display devices such as a liquid crystal display device, an organic light-emitting display device, a plasma display device, and/or the like is increasing.

Recently, display devices may be manufactured utilizing high-resolution micro-OLEDs. The high-resolution micro-OLEDs may be organic light-emitting diodes on silicon (OLEDos) provided (e.g., formed) utilizing a semiconductor-related process based on a silicon wafer.

### SUMMARY

One or more embodiments may provide a display device with improved display quality.

One or more embodiments may provide an electronic device including the display device.

A display device according to one or more embodiments of the present disclosure may include a substate including an active portion, a driving transistor including the active portion and a gate electrode above the substrate and overlapping a channel region of the active portion in plan view, a capacitor including capacitor electrodes sequentially arranged above the gate electrode in a direction away from the substrate, a data line above the capacitor electrodes and configured to receive a data voltage, a direct current voltage line between the capacitor electrodes and the data line, configured to receive a direct current voltage, and overlapping the data line in plan view, and a light-emitting layer above the data line.

In one or more embodiments, a portion of the data line overlapping the capacitor electrodes may be covered by the direct current voltage line.

In one or more embodiments, a width of the direct current voltage line may be substantially equal to or greater than a width of the data line.

In one or more embodiments, a thickness of the direct current voltage line and a thickness of the data line may be greater than respective thicknesses of the capacitor electrodes.

In one or more embodiments, the direct current voltage may include a power voltage.

In one or more embodiments, the display device may further include a voltage connection electrode under the direct current voltage line and coupled to the direct current voltage line through a first contact hole, and a data connection electrode under the data line and coupled to the data line through a second contact hole, where the data line may include a first portion coupled to the data connection electrode and extending in a first direction and a second portion extending in a second direction crossing the first direction and covering the voltage connection electrode.

In one or more embodiments, the display device may further include a first pixel connection electrode in a same layer as the direct current voltage line, a second pixel connection electrode in a same layer as the data line and coupled to the first pixel connection electrode through a contact hole, and a pixel electrode above the second pixel connection electrode, electrically coupled to the second pixel connection electrode, and below the light-emitting layer.

In one or more embodiments, the capacitor electrodes may include a first-first capacitor electrode and a first-second capacitor electrode above the gate electrode, a second-first capacitor electrode and a second-second capacitor electrode respectively above the first-first capacitor electrode and the first-second capacitor electrode, a third-first capacitor electrode and a third-second capacitor electrode respectively above the second-first capacitor electrode and the second-second capacitor electrode, and a fourth-first capacitor electrode and a fourth-second capacitor electrode respectively above the third-first capacitor electrode and the third-second capacitor electrode.

In one or more embodiments, the first-first capacitor electrode, the second-first capacitor electrode, the third-first capacitor electrode, and the fourth-first capacitor electrode may be coupled to each other through third contact holes, where the first-second capacitor electrode, the second-second capacitor electrode, the third-second capacitor electrode, and the fourth-second capacitor electrode may be coupled to each other through fourth contact holes, where the first-first capacitor electrode is electrically coupled to a source region of the active portion, and where the first-second capacitor electrode is electrically coupled to the gate electrode.

In one or more embodiments, the first-first capacitor electrode, the second-second capacitor electrode, the third-first capacitor electrode, and the fourth-second capacitor electrode may overlap each other in plan view, and where the first-second capacitor electrode, the second-first capacitor electrode, the third-second capacitor electrode, and the fourth-first capacitor electrode overlap each other in plan view.

In one or more embodiments, the first-first capacitor electrode, the second-first capacitor electrode, the third-first capacitor electrode, and the fourth-first capacitor electrode may overlap each other in plan view, and where the first-second capacitor electrode, the second-second capacitor electrode, the third-second capacitor electrode, and the fourth-second capacitor electrode may overlap each other in plan view.

In one or more embodiments, the capacitor electrodes may include a first-first capacitor electrode and a first-second capacitor electrode above the gate electrode, a second-first capacitor electrode and a second-second capacitor electrode respectively above the first-first capacitor electrode and the first-second capacitor electrode, and a third-first capacitor electrode and a third-second capacitor electrode respectively above the second-first capacitor electrode and the second-second capacitor electrode, wherein the first-first capacitor electrode, the second-first capacitor electrode, and the third-first capacitor electrode are coupled to each other through third contact holes, where the first-second capacitor electrode, the second-second capacitor electrode, and the third-second capacitor electrode may be coupled to each other through fourth contact holes, where the first-first capacitor electrode may be electrically coupled to a source region of the active portion, and where the first-second capacitor electrode may be electrically coupled to the gate electrode.

In one or more embodiments, a thickness of the data line may be greater than a thickness of the direct current voltage line.

In one or more embodiments, the display device may include a voltage connection line under the direct current voltage line, coupled to the direct current voltage line through a contact hole, and surrounding the capacitor in plan view.

An electronic device according to one or more embodiments of the present disclosure may include a display device including a silicon wafer substate icnluding an active portion, a driving transistor including the active portion and a gate electrode above the silicon wafer substrate and overlapping a channel region of the active portion in plan view, a capacitor comprising capacitor electrodes sequentially arranged above the gate electrode in a direction away from the silicon wafer substrate, a data line above the capacitor electrodes and configured to receive a data voltage, a direct current voltage line between the capacitor electrodes and the data line, configured to receive a direct current voltage, and overlapping the data line in plan view, and a light-emitting layer above the data line, and a processor configured to provide an input image date and a control signal to the display device to control the display device.

In one or more embodiments, a portion of the data line overlapping the capacitor electrodes may be covered by the direct current voltage line.

In one or more embodiments, a width of the direct current voltage line may be substantially equal to or greater than a width of the data line.

In one or more embodiments, a thickness of the direct current voltage line and a thickness of the data line may be greater than respective thicknesses of the capacitor electrodes.

In one or more embodiments, the display device may further include a first pixel connection electrode in a same layer as the direct current voltage line, a second pixel connection electrode in a same layer as the data line and coupled to the first pixel connection electrode through a contact hole, and a pixel electrode above the second pixel connection electrode and electrically coupled to the second pixel connection electrode, where the light-emitting layer may be above the pixel electrode.

In one or more embodiments, the capacitor electrodes may include a first-first capacitor electrode and a first-second capacitor electrode above the gate electrode, a second-first capacitor electrode and a second-second capacitor electrode respectively above the first-first capacitor electrode and the first-second capacitor electrode, a third-first capacitor electrode and a third-second capacitor electrode respectively above the second-first capacitor electrode and the second-second capacitor electrode, and a fourth-first capacitor electrode and a fourth-second capacitor electrode respectively above the third-first capacitor electrode and the third-second capacitor electrode, where the first-first capacitor electrode, the second-first capacitor electrode, the third-first capacitor electrode, and the fourth-first capacitor electrode may be coupled to each other through third contact holes, where the first-second capacitor electrode, the second-second capacitor electrode, the third-second capacitor electrode, and the fourth-second capacitor electrode may be coupled to each other through fourth contact holes, where the first-first capacitor electrode is electrically coupled to a source region of the active portion, and where the first-second capacitor electrode is electrically coupled to the gate electrode.

A display device according to one or more embodiments of the present disclosure may include a plurality of capacitor electrodes sequentially located in (e.g., disposed in) a direction away from a substrate, constituting a capacitor, a data line that may be located on (e.g., disposed on, or above) the plurality of capacitor electrodes and receives a data voltage, and a direct current voltage line, which may be located between (e.g., disposed between) the plurality of capacitor electrodes and the data line to receive a direct current voltage (e.g., to receive a power supply voltage or an initialization voltage), and overlap the data line in plan view. A width of the direct current voltage line may be equal to or greater than a width of the data line. Accordingly, the direct current voltage line may shield a formation of a coupling capacitor between the data line and a first electrode of the capacitor.

In addition, a thickness of the data line may be greater than a thickness of the plurality of capacitor electrodes. Accordingly, a resistance of the data line may be reduced or minimized.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a block diagram schematically illustrating the display device of FIG. 1.

FIG. 3 is an equivalent circuit diagram illustrating a circuit structure of one pixel of FIGS. 1 and 2.

FIG. 4 is a cross-sectional view schematically illustrating a display panel of FIGS. 1 and 2.

FIG. 5 is a cross-sectional view schematically illustrating a driving circuit layer of FIG. 4.

FIG. 6 is a layout view illustrating transistors arranged in a pixel circuit area included in a display area of FIG. 4.

FIGS. 7, 8, 9, 10, 11, 12, 13, and 14 are layout views each illustrating a plurality of metal layers on the transistors of FIG. 6.

FIG. 15 is a cross-sectional view of the plurality of metal layers taken along the line I-I’ of FIG. 14.

FIG. 16 is a cross-sectional view of the plurality of metal layers taken along the lines II-II’ and III-III’ of FIG. 14.

FIG. 17 is a cross-sectional view of the plurality of metal layers taken along the line IV-IV’ of FIG. 14.

FIG. 18 is a cross-sectional view illustrating an example of a capacitor of FIG. 15.

FIG. 19 is a cross-sectional view illustrating an example of third, fourth, fifth, sixth, and seventh metal layers of FIG. 15.

FIG. 20 is a cross-sectional view illustrating an example of third, fourth, fifth, sixth, seventh, and eighth metal layers of FIG. 15.

FIG. 21 is a plan view illustrating a capacitor and voltage connection lines of FIG. 20.

FIG. 22 is a block diagram illustrating an electronic device according to one or more embodiments of the present disclosure.

FIG. 23 is a schematic diagram illustrating an electronic device according to one or more suitable embodiments of the present disclosure.

### DETAILED DESCRIPTION

Hereinafter, a display device and an electronic device including the same according to one or more embodiments of the present disclosure will be explained in more detail with reference to the accompanying drawings. The same reference numerals are utilized for the same components in the drawings, and redundant descriptions of the same components will not be repeated here. The described embodiments, however, may be embodied in one or more suitable different forms, and should not be construed as being limited to only the illustrated embodiments herein. Rather, these embodiments are provided as examples so that the present disclosure will be thorough and complete, and will fully convey the aspects of the present disclosure to those skilled in the art. Accordingly, processes, elements, and techniques that are not necessary to those having ordinary skill in the art for a complete understanding of the aspects of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

One or more suitable embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved shapes and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit or scope of the present disclosure and equivalents thereof.

In the detailed description, for the purposes of explanation, numerous specific details are set forth to provide a thorough understanding of one or more suitable embodiments. It is apparent, however, that one or more suitable embodiments may be practiced without these specific details or with one or more equivalent arrangements. In other instances, well-known structures and devices are shown in block diagram form to avoid unnecessarily obscuring one or more suitable embodiments.

Spatially relative terms, such as “beneath,” “below,” “lower,” “under,” “above,” “upper,” and the like, may be utilized herein for ease of explanation to describe one element’s relationship to another element(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements would then be oriented “above” the other elements. Thus, the example terms “below” and “under” can encompass both an orientation of above and below. The device may be otherwise oriented (e.g., rotated 90 degrees or at other orientations) and the spatially relative descriptors utilized herein should be interpreted accordingly. Similarly, if a first part is described as being arranged “on” a second part, this indicates that the first part is arranged at an upper side or a lower side of the second part without the limitation to the upper side thereof on the basis of the gravity direction.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as "at least one of A and/or B" may include A, B, or A and B. As utilized herein, the term “and/or” includes any and all combinations of one or more of the associated listed items. For example, the expression such as "A and/or B" may include A, B, or A and B.

Further, the use of “may” when describing embodiments of the present disclosure refers to “one or more embodiments of the present disclosure.”

The same reference numerals refer to the same components. Further, in the drawings, the thickness, the ratio, and the dimension of components are exaggerated for effective description of technical contents. The expression “and/or” includes one or more combinations that associated components are capable of defining.

It will be understood that, although the terms “first,” “second,” etc. may be utilized herein to describe one or more suitable components, the components should not be limited by the terms. The terms are only utilized to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology utilized herein is for the purpose of describing particular embodiments only and is not intended to be limiting of the present disclosure. As utilized herein, the singular forms “a” and “an” are intended to include the plural forms as well, unless the context clearly indicates otherwise.

In the present disclosure, it will be understood that the terms “include/includes/including,” “comprise/comprises/comprising,” or “have/has/having,” specifies the presence of stated features, integers, numbers, steps, operations, elements, and/or components, but do not preclude the presence or addition of one or more other features, integers, numbers, steps, operations, elements, components, and/or groups thereof. Additionally, the terms “include/includes/including,” “comprise/comprises/comprising,” or “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the term “substantially,” “about,” “approximately,” and similar terms are utilized as terms of approximation and not as terms of degree, and are intended to account for the inherent deviations in measured or calculated values that would be recognized by those of ordinary skill in the art. “About” or “approximately,” as utilized herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Unless otherwise defined, all terms (including technical terms and scientific terms) utilized in the specification have the same meaning as commonly understood by those skilled in the art to which the present disclosure belongs. Further, terms such as terms defined in the dictionaries commonly utilized should be interpreted as having a meaning consistent with the meaning in the context of the related technology and should not be interpreted in overly ideal or overly formal meanings unless explicitly defined herein.

It will be understood that if a component (e.g., an element, an area, a layer, a part, a portion, a region, and/or the like) is referred to as being “on,” “formed on,” “disposed on,” “connected to,” “connected with,” or “coupled to” another component, this refers to that the component may be directly or indirectly on, formed on, disposed on, connected to, connected with, or coupled to the other component, such that one or more intervening components may be present therebetween. For example, when an element, layer, part, portion, region, or component is referred to as being "electrically connected" or "electrically coupled" to another element, layer, part, portion, region, or component, it can be directly electrically connected or coupled to the other element, layer, part, portion, region, or component, or intervening elements, layers, parts, portions, regions, or components may be present. However, “directly connected/directly coupled” refers to one component directly connecting or coupling another component without any intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

Identical reference numerals refer to substantially identical components. Additionally, in the drawings, the thicknesses, proportions, and dimensions of components are exaggerated for effective description. As utilized herein, the term “and/or” includes all of one or more combinations defined by related components.

Terms such as first, second, and/or the like may be utilized to describe one or more suitable components, but the components should not be limited by the terms. The terms may be utilized only for distinguishing one component from other components. For example, without departing the scope of the present disclosure, a first component may be referred to as a second component, and similarly, the second component may also be referred to as the first component. The terms of a singular form may include plural forms unless otherwise specified.

Unless otherwise defined, all terms utilized herein, including technical or scientific terms, have the same meanings as those generally understood by those skilled in the art to which the present disclosure pertains. Such terms as those defined in a generally utilized dictionary are to be interpreted as having meanings equal to the contextual meanings in the relevant field of art, and are not to be interpreted as having ideal or excessively (or substantially) formal meanings unless clearly defined as having such in the present application.

In the present disclosure, a plane may be defined along a first direction D1 and a second direction D2 crossing (e.g., intersecting) the first direction D1. For example, the first direction D1 and the second direction D2 may be perpendicular to each other. In addition, a third direction D3 may be perpendicular to the plane. Further, in the present disclosure, the phrase “on a plane,” or “in plan view” may mean viewing a target portion from the top, and the phrase “on a cross-section” may mean viewing a cross-section formed by vertically cutting a target portion from the side.

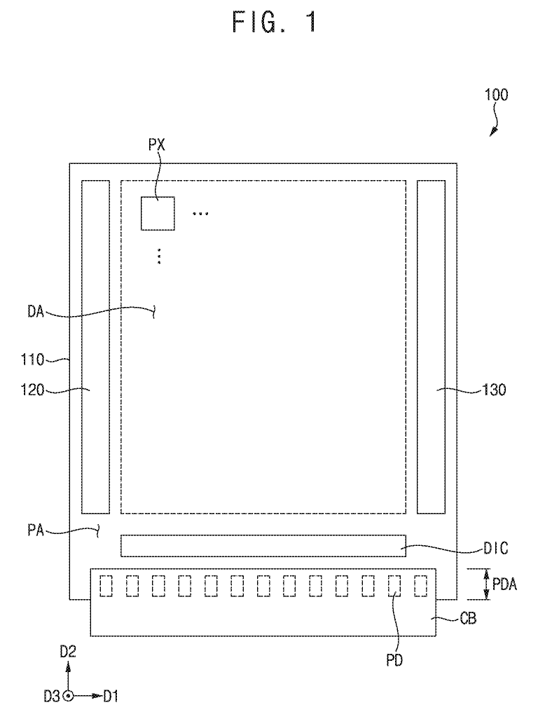

FIG. 1 is a plan view illustrating a display device according to one or more embodiments of the present disclosure.

Referring to FIG. 1, a display device 100 according to one or more embodiments of the present disclosure may include a display panel 110, a driver integrated circuit DIC, and/or a circuit board CB.

The display device 100 may have a rectangular planar shape (e.g., a rectangular planar shape with rounded corners). However, one or more embodiments of the present disclosure are not limited thereto, and the display device 100 may have one or more suitable planar shapes.

The display panel 110 may include a display area DA and a peripheral area PA. The display area DA may be an area capable of displaying an image by generating light and/or by controlling the transmittance of light provided from an external light source. The peripheral area PA may be an area that may not display an image. The peripheral area PA may be located around the display area DA. For example, the peripheral area PA may be to surround the display area DA (e.g., entirely or substantially).

The display panel 110 may include a plurality of pixels PX arranged in the display area DA. The plurality of pixels PX may be arranged in a matrix provided along the first direction D1 and the second direction D2. However, one or more embodiments of the present disclosure are not limited thereto, and the plurality of pixels PX may be arranged in one or more suitable forms.

Each of the plurality of pixels PX may include a driving element (e.g., a transistor), which may be to generate a driving current, and a light-emitting element coupled to (e.g., electrically connected to) the driving element and generating light based on the driving current. Accordingly, the plurality of pixels PX may be to emit light according to the driving current. By emitting light from the plurality of pixels PX, the display area DA may display an image.

In the display area DA, lines connected to the plurality of pixels PX may be further arranged (e.g., disposed or located). For example, the lines may include a data line, a gate line, an emission control line, and/or the like.

In the peripheral area PA, drivers for driving the plurality of pixels PX may be arranged. For example, the drivers may include a gate driver 120 and an emission driver 130. For example, the gate driver 120 may be arranged in the peripheral area PA adjacent to a left side of the display area DA, and the emission driver 130 may be arranged in the peripheral area PA adjacent to a right side of the display area DA. The plurality of pixels PX may be to emit light based on signals transmitted from the drivers.

The peripheral area PA may include a pad area PDA. The pad area PDA may be located at one side of the display area DA. The pad area PDA may be to extend in the first direction D1.

The driver integrated circuit DIC may be bonded to the pad area PDA on the display panel 110. Accordingly, the driver integrated circuit DIC may be electrically connected to the display panel 110.

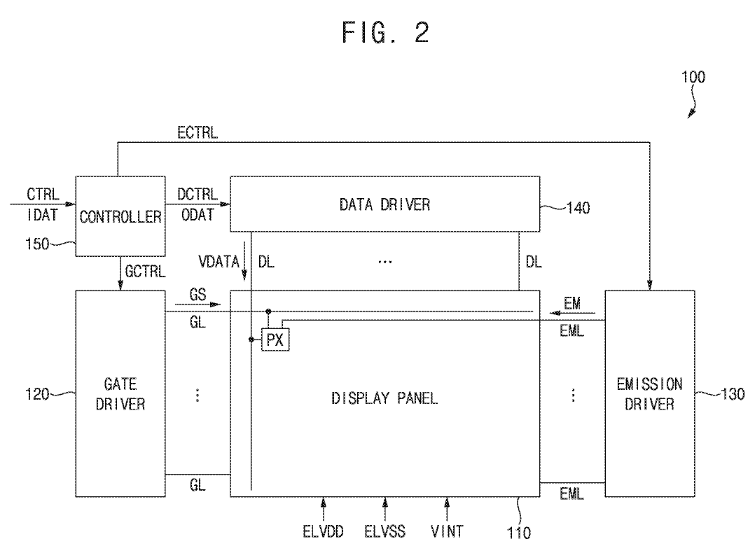

The driver integrated circuit DIC may convert a digital data signal among driving signals into an analog data signal and provide the analog data signal to the plurality of pixels PX. For example, the driving integrated circuit DIC may be a data driver (e.g., the data driver 140 of FIG. 2).

The display panel 110 may include a plurality of pads PD arranged in the pad area PDA. The pads PD may be spaced and/or apart (e.g., spaced apart or separated) from each other along the first direction D1. For example, the pads PD may include metal, an alloy, a metal nitride, a conductive metal oxide, a transparent conductive material, and/or the like. These may be utilized alone or in combination with each other.

One end of the circuit board CB may be bonded to the pads PD arranged in the pad area PDA. Accordingly, the circuit board CB may be electrically connected to the display panel 110. The other end of the circuit board CB may be electrically connected to an external device. Signals, voltages, and/or the like generated from the external device may be provided to the driver integrated circuit DIC and the pixels PX through the circuit board CB. For example, the circuit board CB may be a flexible printed circuit board (FPCB), a printed circuit board (PCB), and/or a flexible flat cable (FFC).

In FIG. 1, the driver integrated circuit DIC may be illustrated as being arranged by a chip-on-plastic (COP) method and/or a chip-on-glass (COG) method. However, one or more embodiments of the present disclosure are not limited thereto. For example, the driver integrated circuit DIC may be arranged by a chip-on-film (COF) method.

FIG. 2 is a block diagram schematically illustrating the display device of FIG. 1.

Referring to FIG. 2, a display device 100 according to one or more embodiments of the present disclosure may include the display panel 110, the gate driver 120, the emission driver 130, a data driver 140, and/or a controller 150.

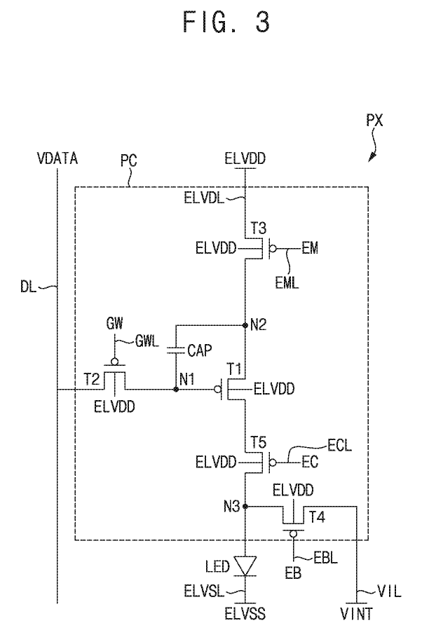

The display panel 110 may include a plurality of gate lines GL, a plurality of data lines DL, a plurality of emission control lines EML, and/or the plurality of pixels PX. The gate lines GL, the emission control lines EML, and/or the data lines DL may be electrically connected to the plurality of pixels PX. The gate lines GL may receive gate signals GS, the emission control lines EML may receive emission control signals EM, and the data lines DL may receive data voltages VDATA. For example, the gate signals GS may include gate signals GW, EB, and EC of FIG. 3.

Each of the gate lines GL may be to extend in a first direction (e.g., a row direction). Each of the emission control lines EML may be to extend in the first direction. Each of the data lines DL may be to extend in a second direction (e.g., a column direction) crossing (e.g., intersecting) the first direction. The gate lines GL, the emission control lines EML, and the data lines DL may be insulated from each other. The plurality of pixels PX may be arranged in areas where the gate lines GL (or the emission control lines EML) cross (e.g., intersect) the data lines DL.

In one or more embodiments, each of the plurality of pixels PX may include a switching transistor, which may provide the data voltage VDATA in response to the gate signal GS, a storage capacitor, which may store the data voltage VDATA provided by the switching transistor, a driving transistor, which may be to generate a driving current based on the data voltage VDATA stored in the storage capacitor, and a light-emitting element, which may be to emit light based on the driving current generated by the driving transistor. For example, the light-emitting element may include a light-emitting diode (LED), an organic light-emitting diode (OLED), and/or a quantum dot (QD) light-emitting element.

The plurality of pixels PX may receive a first power voltage ELVDD and a second power voltage ELVSS. The plurality of pixels PX may receive the data voltage VDATA in response to the gate signal GS and the emission control signal EM, and may be to generate light of a gray level corresponding to the data voltage VDATA utilizing the first power voltage ELVDD and the second power voltage ELVSS. In addition, the plurality of pixels PX may be further to receive an initialization voltage VINT.

The gate driver 120 may provide the gate signals GS to the plurality of pixels PX through the gate lines GL based on a gate control signal GCTRL received from the controller 150. In one or more embodiments, the gate driver 120 may sequentially provide the gate signals GS to the plurality of pixels PX in units (e.g., groups) of rows. In addition, the gate control signal GCTRL may include a gate start signal, a gate clock signal, and/or the like, but one or more embodiments of the present disclosure are not limited thereto. For example, the gate driver 120 may be integrated or provided in a peripheral portion of the display panel 110. Alternatively, the gate driver 120 may be implemented with one or more integrated circuits (ICs).

The emission driver130 may provide the emission control signals EM to the plurality of pixels PX through the emission control lines EML based on an emission control signal ECTRL received from the controller 150. In one or more embodiments, the emission driver 130 may sequentially provide the emission control signals EM to the plurality of pixels PX in units (e.g., groups) of rows. In addition, the emission control signal ECTRL may include an emission start signal, an emission clock signal, and/or the like, but one or more embodiments of the present disclosure are not limited thereto. For example, the emission driver 130 may be integrated or provided in the peripheral portion of the display panel 110. Alternatively, the emission driver 130 may be implemented with one or more integrated circuits (ICs).

The data driver 140 may receive a data control signal DCTRL and an output image data ODAT from the controller 150, and may provide the data voltages VDATA to the pixels PX through the data lines DL based on the data control signal DCTRL and the output image data ODAT. In addition, the data control signal DCTRL may include an output data enable signal, a horizontal start signal, a load signal, and/or the like, but one or more embodiments of the present disclosure are not limited thereto. For example, the data driver 140 may be implemented as a single integrated circuit, and the integrated circuit (e.g., the single integrated circuit) may be referred to as a timing controller embedded data driver (TED). Alternatively, the data driver 140 may be implemented with separate integrated circuits.

The controller 150 may receive an input image data IDAT and a control signal CTRL from an external host processor. For example, the controller 150 may be a timing controller, and the external host processor may include at least one of a central processing unit (CPU) (e.g., a central processor or a central processing circuit), an application processor (AP), a graphic processing unit (GPU) (e.g., a graphic processor or a graphic processing circuit), a communication processor (CP), and/or an image signal processor (ISP). In one or more embodiments, the input image data IDAT may be RGB image data including red image data, green image data, and blue image data. In addition, the control signal CTRL may include a vertical synchronization signal, a horizontal synchronization signal, an input data enable signal, a master clock signal, and/or the like, but one or more embodiments of the present disclosure are not limited thereto.

The controller 150 may be to generate the gate control signal GCTRL, the emission control signal ECTRL, the data control signal DCTRL, and the output image data ODAT based on the input image data IDAT and the control signals CTRL. The controller 150 may provide the gate control signal GCTRL to the gate driver 120 to control operation(s) of the gate driver 120. The controller 150 may provide the emission control signal ECTRL to the emission driver 130 to control operation of the emission driver 130. In addition, the controller 150 may provide the output image data ODAT and the data control signal DCTRL to the data driver 140 to control operation of the data driver 140. For example, the controller 150 may control driving of the display panel 110 based on the input image data IDAT and the control signal CTRL.

FIG. 3 is an equivalent circuit diagram illustrating a circuit structure of one pixel of FIGS. 1 and 2.

Referring to FIG. 3, one pixel PX may include a pixel-driving circuit part PC and a light-emitting element LED electrically connected to the pixel-driving circuit part PC. The pixel-driving circuit part PC may be to generate a driving current, and the light-emitting element LED may be to generate light based on the driving current.

In one or more embodiments, the pixel-driving circuit part PC may include a first transistor T1, a second transistor T2, a third transistor T3, a fourth transistor T4, a fifth transistor T5, and/or a capacitor CAP.

In one or more embodiments, the first transistor T1, the second transistor T2, the third transistor T3, the fourth transistor T4, and the fifth transistor T5 may all be p-channel metal-oxide-semiconductor (PMOS) transistors. However, one or more embodiments of the present disclosure are not limited thereto, and some of the first transistor T1, the second transistor T2, the third transistor T3, the fourth transistor T4, and the fifth transistor T5 may be n-channel metal-oxide-semiconductor (NMOS) transistors, and the rest may be PMOS transistors.

In one or more embodiments, the first transistor T1, the second transistor T2, the third transistor T3, the fourth transistor T4, and the fifth transistor T5 may be metal-oxide-semiconductor field-effect transistors (MOSFETs) provided by a semiconductor-related process. For example, the first transistor T1, the second transistor T2, the third transistor T3, the fourth transistor T4, and the fifth transistor T5 may be provided on a silicon wafer substrate (as used herein, “on” may mean “above”).

The first transistor T1 may include a gate electrode, a first electrode, and/or a second electrode. The gate electrode of the first transistor T1 may be connected to a first node N1. The first electrode of the first transistor T1 may be connected to a second node N2. The second electrode of the first transistor T1 may be connected to a first electrode of the fifth transistor T5. The first transistor T1 may provide the driving current to the light-emitting element LED. The first transistor T1 may be referred to as a driving transistor.

The first transistor T1 may further include a body electrode. The body electrode of the first transistor T1 may receive the first power voltage ELVDD. For example, a first power voltage line ELVDL, which may receive the first power voltage ELVDD, may be connected to the body electrode of the first transistor T1. Alternatively, a different direct current voltage may be applied to the body electrode of the first transistor T1 instead of the first power voltage ELVDD.

The second transistor T2 may include a gate electrode, a first electrode, and a second electrode. The gate electrode of the second transistor T2 may be connected to a first gate line GWL, which may receive the first gate signal GW. The first electrode of the second transistor T2 may be connected to the data line DL, which may receive the data voltage VDATA. The second electrode of the second transistor T2 may be connected to the first node N1.

The second transistor T2 may further include a body electrode. The body electrode of the second transistor T2 may receive the first power voltage ELVDD. For example, the body electrode of the second transistor T2 may be connected to the first power voltage line ELVDL, which may receive the first power voltage ELVDD. Alternatively, a different direct current voltage may be applied to the body electrode of the second transistor T2 instead of the first power voltage ELVDD.

The second transistor T2 may be turned on or off in response to the first gate signal GW. For example, in case that the first gate signal GW may have an active level, the second transistor T2 may be turned on. In this case, the second transistor T2 may provide the data voltage VDATA to the first node N1. Conversely, in case that the first gate signal GW may have an inactive level, the second transistor T2 may be turned off. In this case, the second transistor T2 may block supply of the data voltage VDATA.

The third transistor T3 may include a gate electrode, a first electrode, and/or a second electrode. The gate electrode of the third transistor T3 may be connected to the emission control line EML, which may receive an emission control signal EM. The first electrode of the third transistor T3 may be connected to the first power voltage line ELVDL, which may receive the first power voltage ELVDD. The second electrode of the third transistor T3 may be connected to the second node N2.

The third transistor T3 may further include a body electrode. The body electrode of the third transistor T3 may receive the first power voltage ELVDD. For example, the body electrode of the third transistor T3 may be connected to the first power voltage line ELVDL receiving the first power voltage ELVDD. Alternatively, a different direct current voltage may be applied to the body electrode of the third transistor T3 instead of the first power voltage ELVDD.

The third transistor T3 may be turned on or off in response to the emission control signal EM. For example, in case that the emission control signal EM may have an active level, the third transistor T3 may be turned on. In this case, the third transistor T3 may provide the first power voltage ELVDD to the second node N2. Conversely, in case that the emission control signal EM may have an inactive level, the third transistor T3 may be turned off. In this case, the third transistor T3 may block supply of the first power voltage ELVDD.

The fourth transistor T4 may include a gate electrode, a first electrode, and/or a second electrode. The gate electrode of the fourth transistor T4 may be connected to a second gate line EBL, which may receive the second gate signal EB. The first electrode of the fourth transistor T4 may be connected to an initialization line VIL, which may receive the initialization voltage VINT. The second electrode of the fourth transistor T4 may be connected to a third node N3.

The fourth transistor T4 may further include a body electrode. The body electrode of the fourth transistor T4 may receive the first power voltage ELVDD. For example, the body electrode of the fourth transistor T4 may be connected to the first power voltage line ELVDL receiving the first power voltage ELVDD. Alternatively, a different direct current voltage may be applied to the body electrode of the fourth transistor T4 instead of the first power voltage ELVDD.

The fourth transistor T4 may be turned on or off in response to the second gate signal EB. For example, in case that the second gate signal EB has an active level, the fourth transistor T4 may be turned on. In this case, the fourth transistor T4 may provide the initialization voltage VINT to the third node N3. Conversely, in case that the second gate signal EB has an inactive level, the fourth transistor T4 may be turned off. In this case, the fourth transistor T4 may block supply of the initialization voltage VINT.

The fifth transistor T5 may include a gate electrode, a first electrode, and/or a second electrode. The gate electrode of the fifth transistor T5 may be connected to a third gate line ECL, which may receive the third gate signal EC. The first electrode of the fifth transistor T5 may be connected to the second electrode of the first transistor T1. The second electrode of the fifth transistor T5 may be connected to the third node N3.

The fifth transistor T5 may further include a body electrode. The body electrode of the fifth transistor T5 may receive the first power voltage ELVDD. For example, the body electrode of the fifth transistor T5 may be connected to the first power voltage line ELVDL, which may receive the first power voltage ELVDD. Alternatively, a different direct current voltage may be applied to the body electrode of the fifth transistor T5 instead of the first power voltage ELVDD.

The fifth transistor T5 may be turned on or off in response to the third gate signal EC. For example, in case that the third gate signal EC has an active level, the fifth transistor T5 may be turned on. In this case, the fifth transistor T5 may provide the driving current generated from the first transistor T1 to the third node N3. Conversely, in case that the third gate signal EC has an inactive level, the fifth transistor T5 may be turned off. In this case, the fifth transistor T5 may block supply of the driving current generated from the first transistor T1.

In one or more embodiments, a first electrode of each of the first, second, third, fourth, and fifth transistors T1, T2, T3, T4, and T5 may be a source electrode and a second electrode of each of the first, second, third, fourth, and fifth transistors T1, T2, T3, T4, and T5 may be a drain electrode. However, one or more embodiments of the present disclosure are not limited thereto.

The capacitor CAP may include a first electrode and a second electrode. The first electrode of the capacitor CAP may be connected to the first node N1. The second electrode of the capacitor CAP may be connected to the second node N2. The capacitor CAP may store a differential voltage between a gate voltage and a source voltage of the first transistor T1.

The light-emitting element LED may include an anode electrode and a cathode electrode. The anode electrode of the light-emitting element LED may be connected to the third node N3. The cathode electrode of the light-emitting element LED may be connected to a second power voltage line ELVSL, which may receive the second power voltage ELVSS. The second power voltage ELVSS may have a voltage level lower than a voltage level of the first power voltage ELVDD.

Although FIG. 3 illustrates one pixel-driving circuit part PC including five transistors and one capacitor, one or more embodiments of the present disclosure are not limited thereto.

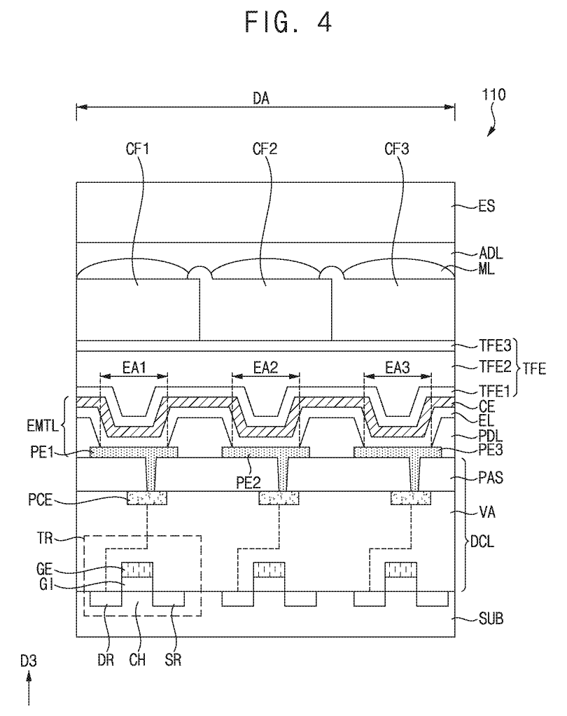

FIG. 4 is a cross-sectional view schematically illustrating a display panel of FIGS. 1 and 2. For example, FIG. 4 is a cross-sectional view illustrating a portion of the display area DA of FIG. 1.

Referring to FIG. 4, the display panel 110 included in the display device 100 according to one or more embodiments of the present disclosure may include a substrate SUB, a driving circuit layer DCL, a light-emitting element layer EMTL, an encapsulation layer TFE, first, second, and third color filter layers CF1, CF2, and CF3, a lens layer, an adhesive layer ADL, and/or an encapsulation substrate ES. The driving circuit layer DCL may include a transistor TR, an interlayer insulating layer VA, a pixel connection electrode PCE, and/or a passivation layer PAS. The light-emitting element layer EMTL may include a pixel-defining layer PDL, first, second, and third pixel electrodes PE1, PE2, and PE3, a light-emitting layer EL, and/or a common electrode CE.

In one or more embodiments, the substrate SUB may include a silicon wafer substrate provided utilizing a semiconductor process. The substrate SUB may be a support for supporting other components of the display device 100. For example, the substrate SUB may include a semiconductor material (e.g., a Group IV semiconductor, a Group III-V compound semiconductor, a Group II-VI semiconductor, and/or the like). However, one or more embodiments of the present disclosure are not limited thereto. In the present disclosure, the substrate SUB may be referred to as a silicon wafer substrate.

The transistor TR may be arranged on (e.g., disposed on or above) the substrate SUB. For example, the transistor TR may correspond to the fourth transistor T4 of FIG. 3.

The transistor TR may include an active portion, a gate-insulating layer GI, and/or a gate electrode GE. A portion of the substrate SUB may define the active portion. For example, the substrate SUB may include the active portion. The active portion may include a source region SR, a drain region DR, and/or a channel region CH.

The substrate SUB may include a semiconductor material. In one or more embodiments, the substrate SUB may be an n-type semiconductor substrate doped with an n-type impurity or a p-type semiconductor substrate doped with a p-type impurity.

The source region SR and the drain region DR may be arranged inside (e.g., disposed inside) the active portion. For example, the source region SR may be arranged at (e.g., disposed at) one side of the active portion, and the drain region DR may be arranged at the other side of the active portion. For example, the source region SR and the drain region DR may include the same semiconductor material as the substrate SUB. The source region SR and the drain region DR may be a source electrode and a drain electrode of the transistor TR, respectively.

The source region SR and the drain region DR may be doped with an impurity. Accordingly, the source region SR and the drain region DR may be conductive regions. The doping concentration of the source region SR and the drain region DR may be higher than the doping concentration of the substrate SUB. In one or more embodiments, the source region SR and the drain region DR may be doped with a p-type impurity. However, one or more embodiments of the present disclosure are not limited thereto.

At least a portion of the substrate SUB in contact with the source region SR and the drain region DR may be doped with an impurity of a type opposite to an impurity of the source region SR and the drain region DR. For example, a well region in contact with the source region SR and the drain region DR and doped with an impurity of a type opposite to an impurity of the source region SR and the drain region DR may be provided inside the substrate SUB. In this case, the substrate SUB may be a semiconductor substrate doped with an impurity of the same type as the source region SR and the drain region DR.

In one or more embodiments, in case that the source region SR and the drain region DR are doped with a p-type impurity, at least a portion of the substrate SUB (e.g., the well region) in contact with the source region SR and the drain region DR may be doped with an n-type impurity.

The channel region CH may be located inside the substrate SUB between the source region SR and the drain region DR. For example, the channel region CH may include the same semiconductor material as the substrate SUB. The channel region CH may be a region of the substrate SUB in which carriers having charges conduct in case that a voltage is applied to the gate electrode GE.

The channel region CH may be defined as a current path provided between the source region SR and the drain region DR. For example, in case that the source region SR and the drain region DR are doped with a p-type impurity, the channel region CH may be provided in case that a negative voltage is applied to the gate electrode GE, and may transmit current through the movement of holes.

The gate-insulating layer GI may be arranged on the substrate SUB. For example, the gate-insulating layer GI may overlap the channel region CH. The gate-insulating layer GI may include silicon oxide (e.g., SiO₂), silicon nitride, and/or an insulating material having a high dielectric constant. The material having a high dielectric constant may refer to a dielectric material having a dielectric constant higher than a dielectric constant of silicon oxide. For example, the material having a high dielectric constant may include aluminum oxide (e.g., Al₂O₃), tantalum oxide (e.g., Ta₂O₃), titanium oxide (e.g., TiO₂), yttrium oxide (e.g., Y₂O₃), zirconium oxide (e.g., ZrO₂), zirconium silicon oxide (e.g., ZrSiₓO_{y}), hafnium oxide (e.g., HfO₂), hafnium silicon oxide (e.g., HfSiₓO_{y}), lanthanum oxide (e.g., La₂O₃), lanthanum aluminum oxide (e.g., LaAlₓO_{y}), lanthanum hafnium oxide (e.g., LaHfₓO_{y}), hafnium aluminum oxide (e.g., HfAlₓO_{y}), praseodymium oxide (e.g., Pr₂O₃), and/or the like. These may be utilized alone or in combination with each other. However, one or more embodiments of the present disclosure are not limited thereto.

The gate electrode GE may be arranged on the gate-insulating layer GI. The gate electrode GE may overlap the channel region CH in plan view. The gate electrode GE may include a metal and/or a metal nitride. Examples of the metal may include aluminum (Al), tungsten (W), copper (Cu), molybdenum (Mo), and/or the like. Examples of the metal nitride may include titanium nitride (e.g., TiN), tantalum nitride (e.g., TaN), tungsten nitride (e.g., WN), and/or the like. These may be utilized alone or in combination with each other. Alternatively, the gate electrode GE may include a semiconductor material such as doped polysilicon. In addition, the gate electrode GE may have a single-layer structure or a multi-layer structure including a plurality of layers.

The interlayer insulating layer VA may be arranged on the substrate SUB and the transistor TR. For example, the interlayer insulating layer VA may include an inorganic material and/or an organic material. The inorganic material may include silicon oxide, silicon nitride, and/or the like. These may be utilized alone or in combination with each other. The interlayer insulating layer VA may have a multi-layer structure including a plurality of layers.

The passivation layer PAS may be arranged on the interlayer insulating layer VA. For example, the passivation layer PAS may include an inorganic material and/or an organic material. The inorganic material may include silicon oxide, silicon nitride, and/or the like. These may be utilized alone or in combination with each other. The passivation layer PAS may have a single-layer structure or a multi-layer structure including a plurality of layers.

The pixel connection electrode PCE may be arranged between the interlayer insulating layer VA and the passivation layer PAS. The pixel connection electrode PCE may be electrically connected to the drain region DR of the transistor TR. For example, the pixel connection electrode PCE may be electrically connected to the drain region DR of the transistor TR through a plurality of metal layers.

The pixel connection electrode PCE may include a metal, an alloy, a metal nitride, a conductive metal oxide, a transparent conductive material, and/or the like. For example, the pixel connection electrode PCE may include copper (Cu), aluminum (Al), tungsten (W), molybdenum (Mo), chromium (Cr), gold (Au), titanium (Ti), nickel (Ni), neodymium (Nd), and/or the like. These may be utilized alone or in combination with each other. The pixel connection electrode PCE may have a single-layer structure or a multi-layer structure including a plurality of layers.

The first, second, and third pixel electrodes PE1, PE2, and PE3 may be arranged on the passivation layer PAS. The first pixel electrode PE1 may be arranged in a first light-emitting area EA1, the second pixel electrode PE2 may be arranged in a second light-emitting area EA2, and the third pixel electrode PE3 may be arranged in a third light-emitting area EA3. The first, second, and third light-emitting areas EA1, EA2, and EA3 may be to emit light of different respective colors. For example, the first light-emitting area EA1 may be to emit light of a first color (e.g., red light), the second light-emitting area EA2 may be to emit light of a second color (e.g., green light), and the third light-emitting area EA3 may be to emit light of a third color (e.g., blue light). However, one or more embodiments of the present disclosure are not limited thereto. The color of light emitted from the light-emitting area may refer to the color finally expressed through the display device 100.

The first, second, and third pixel electrodes PE1, PE2, and PE3 may be connected to the pixel connection electrode PCE through a contact hole penetrating the passivation layer PAS (e.g., the contact hole may be a through hole of the passivation layer PAS), respectively. The first, second, and third pixel electrodes PE1, PE2, and PE3 may include a metal, an alloy, a metal nitride, a conductive metal oxide, a transparent conductive material, and/or the like. For example, the first, second, and third pixel electrodes PE1, PE2, and PE3 may include copper (Cu), aluminum (Al), tungsten (W), molybdenum (Mo), chromium (Cr), gold (Au), titanium (Ti), nickel (Ni), neodymium (Nd), and/or the like. These may be utilized alone or in combination with each other. Each of the first, second, and third pixel electrodes PE1, PE2, and PE3 may have a single-layer structure or a multi-layer structure including a plurality of layers. The first, second, and third pixel electrodes PE1, PE2, and PE3 may be anode electrodes.

The pixel-defining layer PDL may be arranged on the passivation layer PAS. A pixel opening exposing at least a portion of each of the first, second, and third pixel electrodes PE1, PE2, and PE3 may be defined in the pixel-defining layer PDL. In addition, the pixel-defining layer PDL may cover edges of the first, second, and third pixel electrodes PE1, PE2, and PE3. For example, the pixel-defining layer PDL may include an inorganic material such as silicon oxide, silicon nitride, silicon oxynitride, and/or the like. These may be utilized alone or in combination with each other. Alternatively, the pixel-defining layer PDL may include an organic material. In one or more embodiments, the pixel-defining layer PDL may have a multi-layer structure, but one or more embodiments of the present disclosure are not limited thereto.

The light-emitting layer EL may be arranged on the first, second, and third pixel electrodes PE1, PE2, and PE3 and the pixel-defining layer PDL. The light-emitting layer EL may be a common layer provided in the display area DA. For example, the light-emitting layer EL may be to extend continuously over the entire display area DA. For example, the light-emitting layer EL may include a hole injection layer, a hole transport layer, an organic light-emitting layer, an electron injection layer, and/or an electron transport layer. In one or more embodiments, the organic light-emitting layer may include a light-emitting material that may be to emit white light. For example, the white light may be light mixed with blue light, green light, and/or red light. Alternatively, the white light may be light mixed with blue light and yellow light.

However, one or more embodiments of the present disclosure are not limited thereto, and the light-emitting layer EL may include a first light-emitting layer patterned to overlap the first light-emitting area EA1 and including a light-emitting material that may be to emit red light, a second light-emitting layer patterned to overlap the second light-emitting area EA2 and including a light-emitting material that may be to emit green light, and a third light-emitting layer patterned to overlap the third light-emitting area EA3 and including a light-emitting material that may be to emit blue light. In this case, the first, second, and third light-emitting layers may be separated or apart (e.g., spaced apart) from each other, and the first, second, and third color filter layers CF1, CF2, and CF3 may not be repeated here.

The common electrode CE may be arranged on the light-emitting layer EL. The common electrode CE may be a common layer provided in the display area DA. For example, the common electrode CE may be to extend continuously over the entire display area DA. For example, the common electrode CE may include a metal, an alloy, a metal nitride, a conductive metal oxide, a transparent conductive material, and/or the like. These may be utilized alone or in combination with each other. The common electrode CE may be a cathode electrode.

Accordingly, the first pixel electrode PE1, the light-emitting layer EL, and the common electrode CE may form a first light-emitting element in the first light-emitting area EA1, the second pixel electrode PE2, the light-emitting layer EL, and the common electrode CE may form a second light-emitting element in the second light-emitting area EA2, and the third pixel electrode PE3, the light-emitting layer EL, and the common electrode CE may form a third light-emitting element in the third light-emitting area EA3. For example, the first, second, and third light-emitting elements may be to emit light of the same color (e.g., white light). Alternatively, the first, second, and third light-emitting elements may emit light of different respective colors.

The pixel opening of the pixel-defining layer PDL exposing the first pixel electrode PE1 may define the first light-emitting area EA1 of the first light-emitting element, the pixel opening of the pixel-defining layer PDL exposing the second pixel electrode PE2 may define the second light-emitting area EA2 of the second light-emitting element, and the pixel opening of the pixel-defining layer PDL exposing the third pixel electrode PE3 may define the third light-emitting area EA3 of the third light-emitting element.

The encapsulation layer TFE may be arranged on the common electrode CE. The encapsulation layer TFE may be to extend continuously over the entire display area DA. The encapsulation layer TFE may prevent or reduce impurities, moisture, and/or the like from penetrating into the first, second, and third light-emitting elements from the outside.

The encapsulation layer TFE may include at least one inorganic layer and at least one organic layer. For example, the encapsulation layer TFE may include a first inorganic encapsulation layer TFE1, an organic encapsulation layer TFE2 arranged on the first inorganic encapsulation layer TFE1, and a second inorganic encapsulation layer TFE3 arranged on the organic encapsulation layer TFE2. The organic encapsulation layer TFE2 may have a substantially flat upper surface. For example, the first and second inorganic encapsulation layers TFE1 and TFE3 may include silicon oxide, silicon nitride, silicon oxynitride and/or the like. These may be utilized alone or in combination with each other. For example, the organic encapsulation layer TFE2 may include a polymer cured material such as polyacrylate and/or the like.

The first, second, and third color filter layers CF1, CF2, and CF3 may be arranged on the encapsulation layer TFE. The first color filter layer CF1 may overlap the first light-emitting area EA1, the second color filter layer CF2 may overlap the second light-emitting area EA2, and the third color filter layer CF3 may overlap the third light-emitting area EA3. The first, second, and third color filter layers CF1, CF2, and CF3 may selectively transmit light of an example wavelength and absorb light of the remaining wavelengths. For example, the first color filter layer CF1 may transmit light of the first color (e.g., red light), the second color filter layer CF2 may transmit light of the second color (e.g., green light), and the third color filter layer CF3 may transmit light of the third color (e.g., blue light). For example, the first, second, and third color filter layers CF1, CF2, and CF3 may be final structures defining the first, second, and third light-emitting areas EA1, EA2, and EA3, respectively.

The first, second, and third color filter layers CF1, CF2, and CF3 may partially overlap each other in plan view. For example, the first color filter layer CF1 may partially overlap the second color filter layer CF2, and the second color filter layer CF2 may partially overlap the third color filter layer CF3. Accordingly, portions where the first, second, and third color filter layers CF1, CF2, and CF3 overlap may serve as a light-shielding layer. The light-shielding layer may shield incident light and may prevent or reduce color mixing between the first, second, and third light-emitting areas EA1, EA2, and EA3. Alternatively, a separate light-shielding layer may be arranged between the first, second, and third color filter layers CF1, CF2, and CF3. In this case, the separate light-shielding layer may be a black matrix.

The lens layer may be arranged on the first, second, and third color filter layers CF1, CF2, and CF3. The lens layer may include a plurality of microlenses ML. The microlenses ML may improve light extraction efficiency. The microlenses ML may overlap the first, second, and third light-emitting areas EA1, EA2, and EA3, respectively. The microlenses ML may have a refractive index (e.g., a predetermined refractive index) for visible light. For example, the microlenses ML may have a refractive index of about 1.5 or more to about 1.7 or less for visible light. However, one or more embodiments of the present disclosure are not limited thereto. For example, each of the microlenses ML may have a convex cross-sectional shape.

The encapsulation substrate ES may be arranged on the lens layer. The encapsulation substrate ES may be attached to the lens layer through the adhesive layer ADL. The encapsulation substrate ES may protect the display panel 110 from moisture penetration or gas inflow. The encapsulation substrate ES may include a transparent insulating substrate. For example, the encapsulation substrate ES may include glass. For example, the adhesive layer ADL may include an optical clear adhesive (OCA), a pressure sensitive adhesive (PSA), a photo-curable resin, and/or a thermosetting resin.

Unlike as illustrated in FIG. 4, the lens layer and the encapsulation substrate ES may be omitted. In this case, an overcoat layer including a transparent organic material may be arranged on the first, second, and third color filter layers CF1, CF2, and CF3.

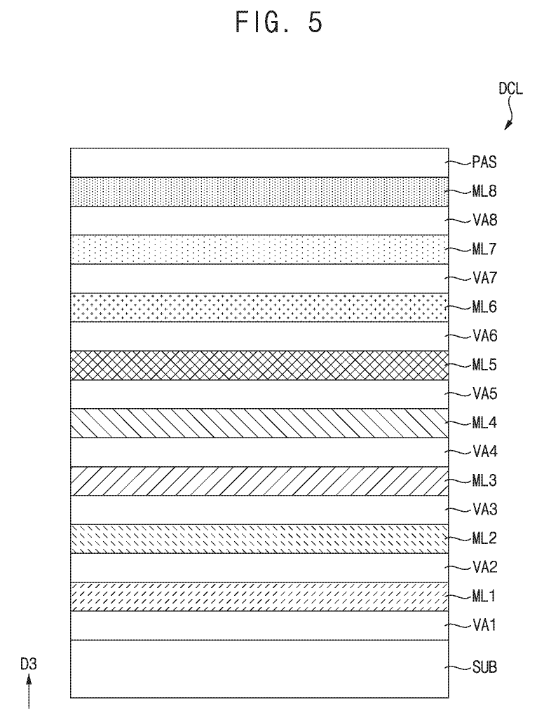

FIG. 5 is a cross-sectional view schematically illustrating a driving circuit layer of FIG. 4.

Referring to FIGS. 4 and 5, the driving circuit layer DCL may include a plurality of metal layers and a plurality of insulating layers alternately arranged along (e.g., disposed along) the third direction D3 on the substrate SUB. In one or more embodiments, the plurality of metal layers may include a first metal layer ML1, a second metal layer ML2, a third metal layer ML3, a fourth metal layer ML4, a fifth metal layer ML5, a sixth metal layer ML6, a seventh metal layer ML7, and/or an eighth metal layer ML8 sequentially arranged along the third direction D3, and the plurality of insulating layers may include a first interlayer insulating layer VA1, a second interlayer insulating layer VA2, a third interlayer insulating layer VA3, a fourth interlayer insulating layer VA4, a fifth interlayer insulating layer VA5, a sixth interlayer insulating layer VA6, a seventh interlayer insulating layer VA7, an eighth interlayer insulating layer VA8, and/or the passivation layer PAS sequentially arranged along the third direction D3.

For example, the first metal layer ML1 may be arranged between the first interlayer insulating layer VA1 and the second interlayer insulating layer VA2, the second metal layer ML2 may be arranged between the second interlayer insulating layer VA2 and the third interlayer insulating layer VA3, the third metal layer ML3 may be between the third interlayer insulating layer VA3 and the fourth interlayer insulating layer VA4, the fourth metal layer ML4 may be arranged between the fourth interlayer insulating layer VA4 and the fifth interlayer insulating layer VA5, the fifth metal layer ML5 may be arranged between the fifth interlayer insulating layer VA5 and the sixth interlayer insulating layer VA6, the sixth metal layer ML6 may be arranged between the sixth interlayer insulating layer VA6 and the seventh interlayer insulating layer VA7, the seventh metal layer ML7 may be arranged between the seventh interlayer insulating layer VA7 and the eighth interlayer insulating layer VA8, and the eighth metal layer ML8 may be arranged between the eighth interlayer insulating layer VA8 and the passivation layer PAS.

For example, the first, second, third, fourth, fifth, sixth, seventh, and eighth metal layers ML1, ML2, ML3, ML4, ML5, ML6, ML7, and ML8 may include copper (Cu), aluminum (Al), tungsten (W), molybdenum (Mo), chromium (Cr), gold (Au), titanium (Ti), nickel (Ni), neodymium (Nd), and/or the like. These may be utilized alone or in combination with each other.

For example, the first, second, third, fourth, fifth, sixth, seventh, and eighth interlayer insulating layers VA1, VA2, VA3, VA4, VA5, VA6, VA7, and VA8 may include an inorganic material and/or an organic material. The inorganic material may include silicon oxide, silicon nitride, and/or the like. These may be utilized alone or in combination with each other.

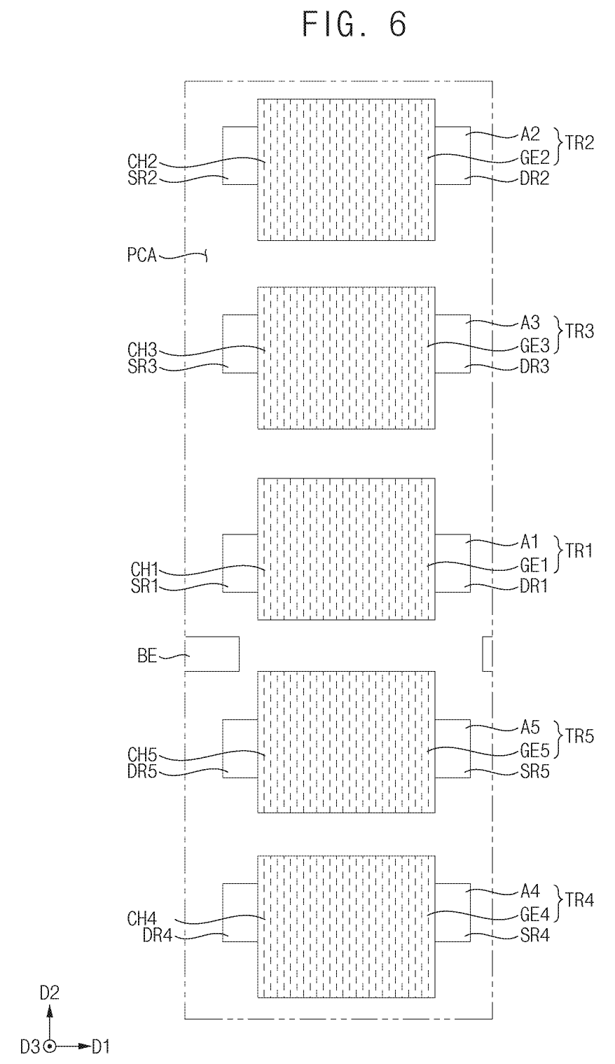

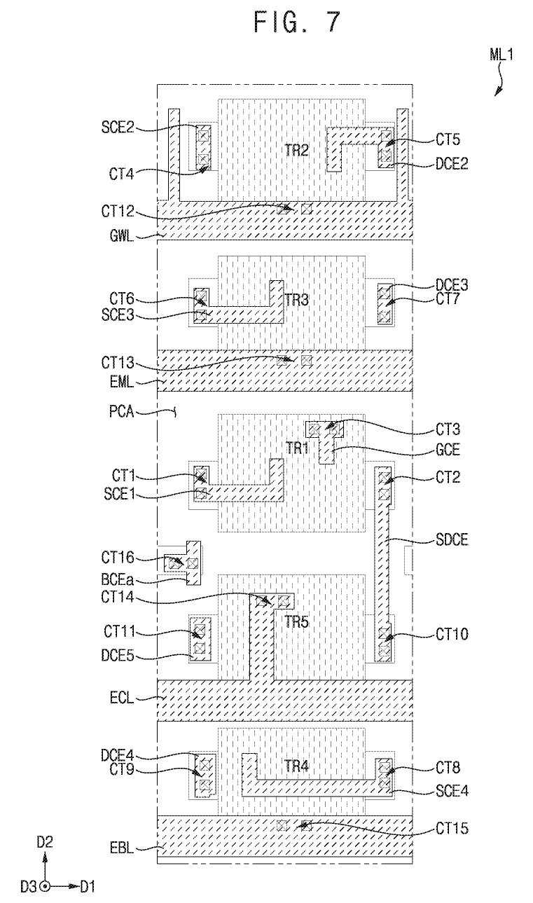

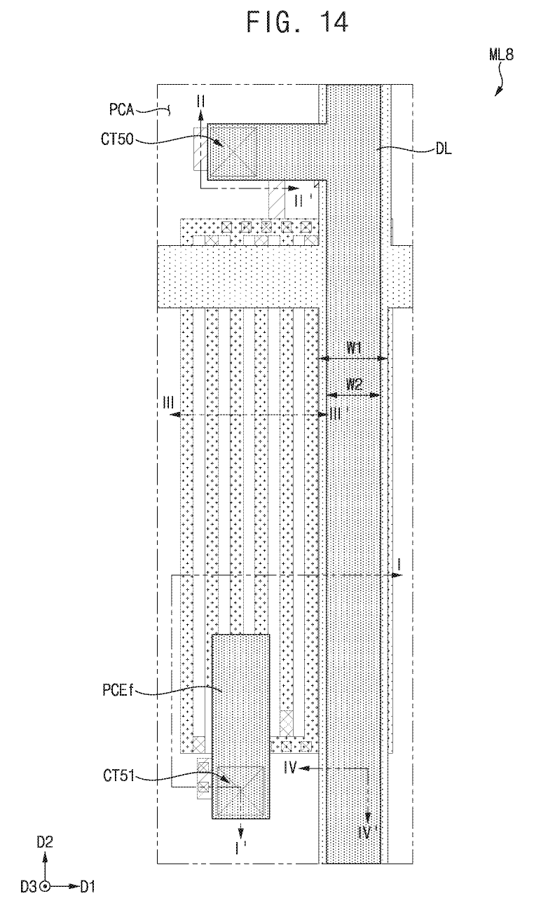

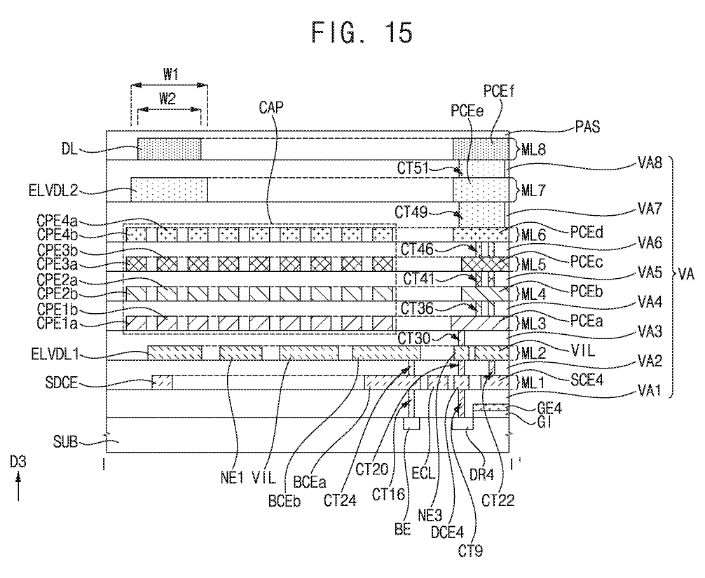

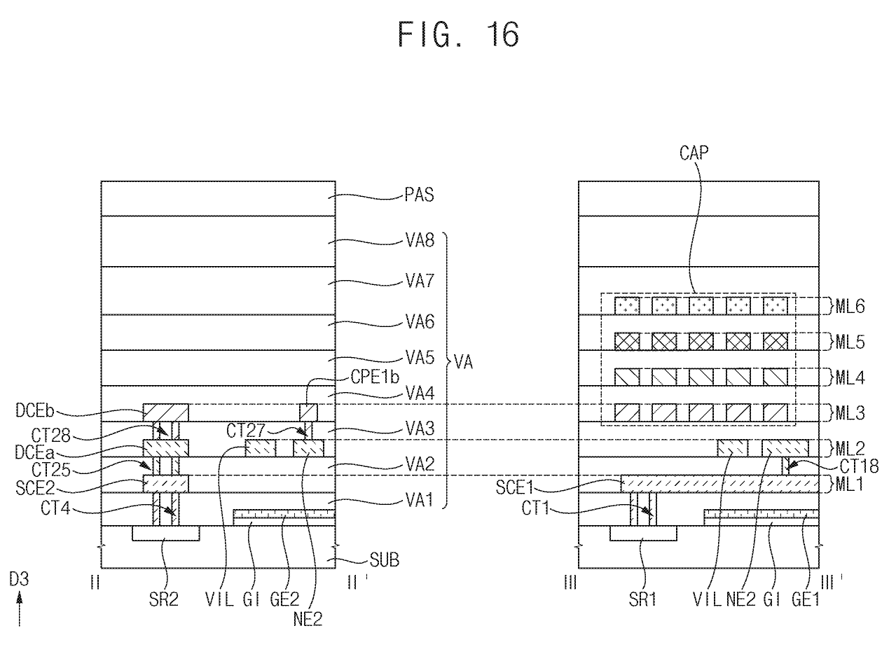

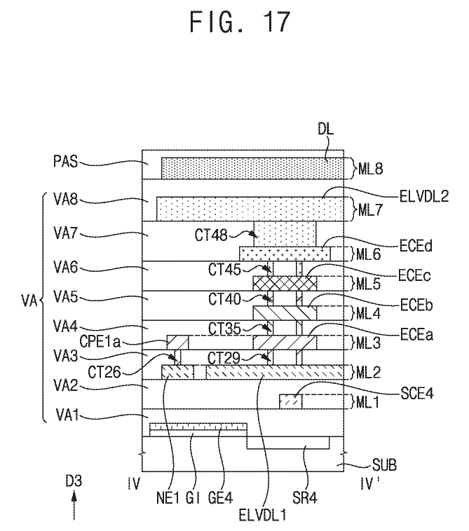

FIG. 6 is a layout view illustrating transistors arranged in a pixel circuit area included in a display area of FIG. 4. FIGS. 7, 8, 9, 10, 11, 12, 13, and 14 are layout views each illustrating a plurality of metal layers arranged on the transistors of FIG. 6. FIG. 15 is a cross-sectional view of the plurality of metal layers taken along the line I-I’ of FIG. 14. FIG. 16 is a cross-sectional view of the plurality of metal layers taken along the line II-II’ and the line III-III’ of FIG. 14. FIG. 17 is a cross-sectional view of the plurality of metal layers taken along the line IV-IV’ of FIG. 14.

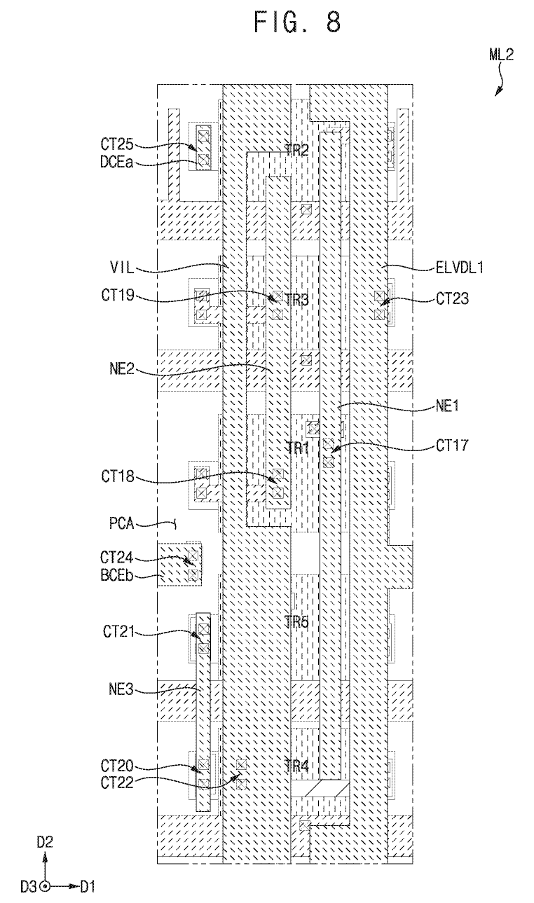

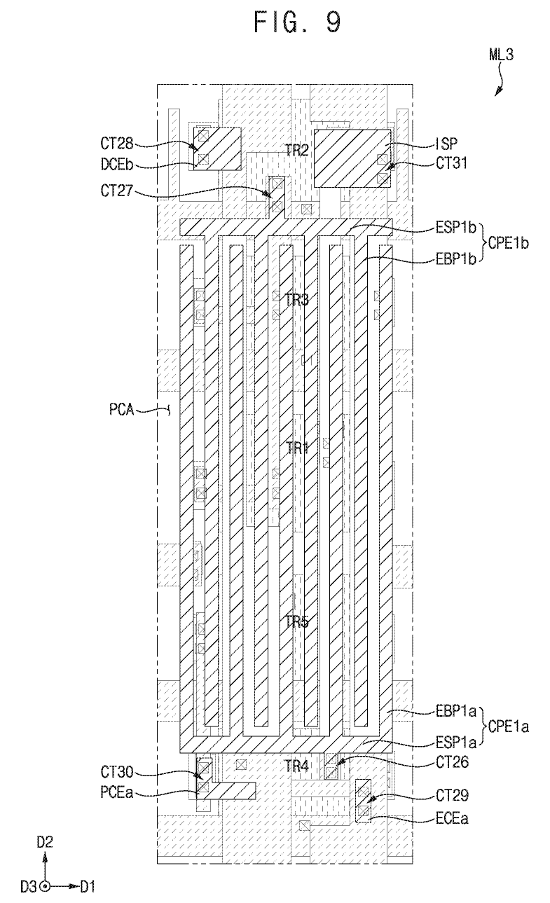

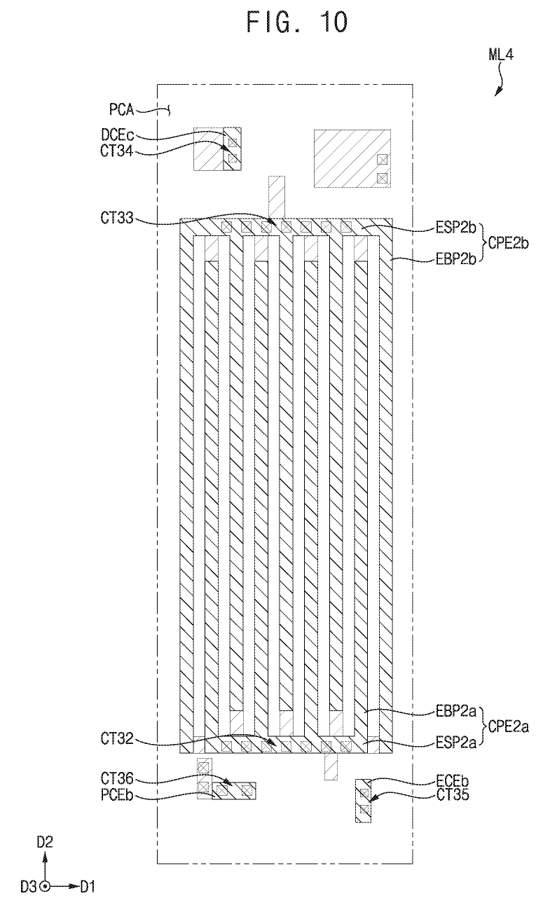

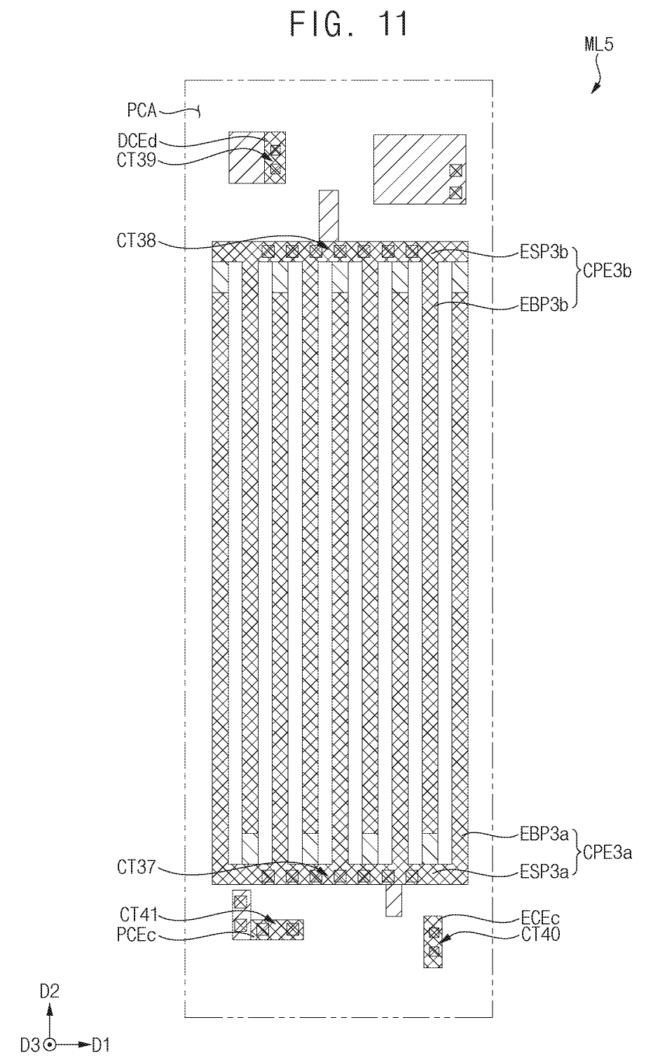

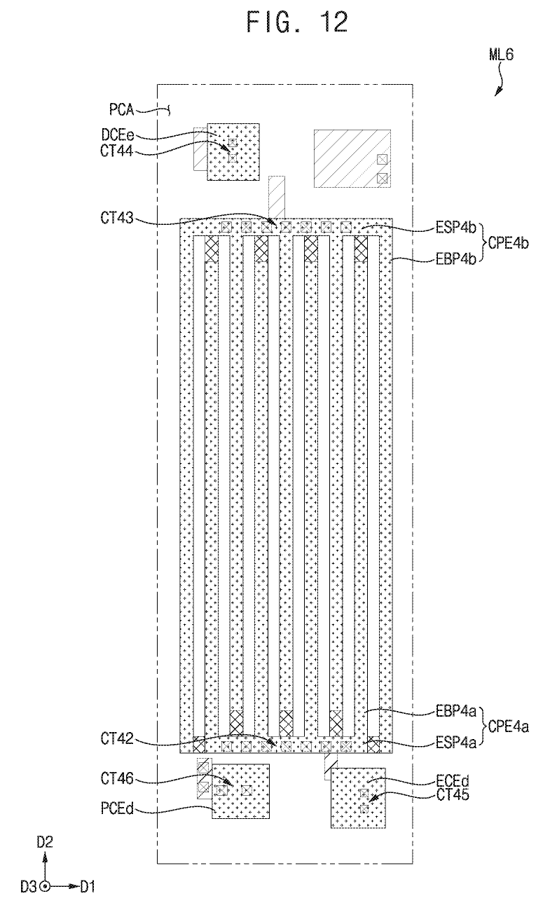

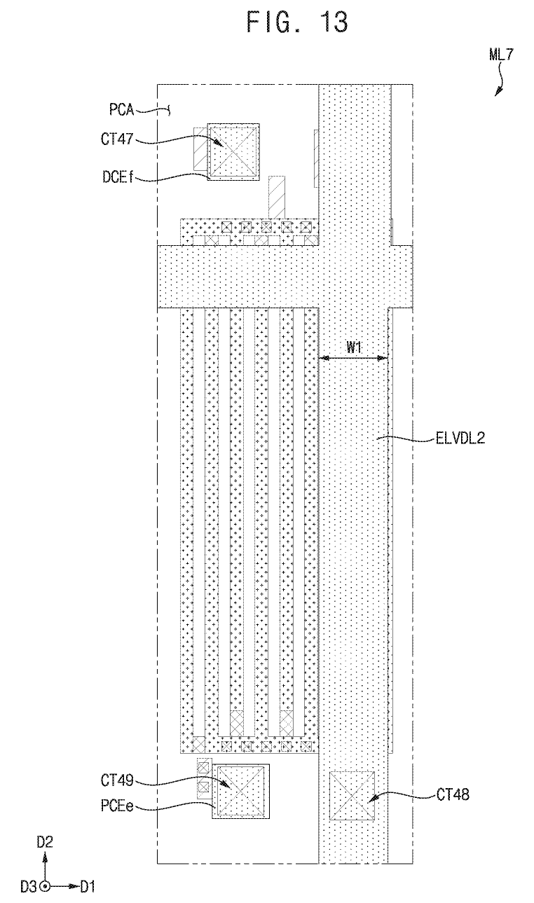

For example, FIG. 7 is a layout view illustrating the first metal layer ML1 of FIG. 5 arranged on the transistors of FIG. 6. FIG. 8 is a layout view illustrating the second metal layer ML2 of FIG. 5 arranged on the first metal layer ML1 of FIG. 7. FIG. 9 is a layout view illustrating the third metal layer ML3 of FIG. 5 arranged on the second metal layer ML2 of FIG. 8. FIG. 10 is a layout view illustrating the fourth metal layer ML4 of FIG. 5 arranged on the third metal layer ML3 of FIG. 9. FIG. 11 is a layout view illustrating the fifth metal layer ML5 of FIG. 5 arranged on the fourth metal layer ML4 of FIG. 10. FIG. 12 is a layout view illustrating the sixth metal layer ML6 of FIG. 5 arranged on the fifth metal layer ML5 of FIG. 11. FIG. 13 is a layout view illustrating the seventh metal layer ML7 of FIG. 5 arranged on the sixth metal layer ML6 of FIG. 12. FIG. 14 is a layout view illustrating the eighth metal layer ML8 of FIG. 5 arranged on the seventh metal layer ML7 of FIG. 13. However, for simplification of the drawings, illustration of the transistors, the first metal layer ML1, and the second metal layer ML2 illustrated in FIGS. 6, 7, and 8 may not be repeated in FIGS. 10, 11, 12, 13, and 14.

Referring to FIGS. 4 and 6, the display area DA may include a pixel circuit area PCA. Gate electrodes, source electrodes and drain electrodes of a plurality of transistors and body electrodes BE of the plurality of transistors may be arranged in the pixel circuit area PCA. The plurality of transistors may include a first transistor TR1, a second transistor TR2, a third transistor TR3, a fourth transistor TR4, and/or a fifth transistor TR5. For example, the first, second, third, fourth, and fifth transistors TR1, TR2, TR3, TR4, and TR5 may correspond to the first, second, third, fourth, and fifth transistors T1, T2, T3, T4, and T5 of FIG. 3, respectively.

The first transistor TR1, the second transistor TR2, the third transistor TR3, the fourth transistor TR4, and the fifth transistor TR5 may be arranged in a row along the second direction D2. In one or more embodiments, the second transistor TR2, the third transistor TR3, the first transistor TR1, the fifth transistor TR5, and the fourth transistor TR4 may be sequentially arranged along a direction opposite to the second direction D2. However, one or more embodiments of the present disclosure are not limited thereto, and positions of the transistors arranged in the pixel circuit area PCA may be interchanged.

The first transistor TR1 may include a first active portion A1 and a first gate electrode GE1 arranged on the first active portion A1, the second transistor TR2 may include a second active portion A2 and a second gate electrode GE2 arranged on the second active portion A2, the third transistor TR3 may include a third active portion A3 and a third gate electrode GE3 arranged on the third active portion A3, the fourth transistor TR4 may include a fourth active portion A4 and a fourth gate electrode GE4 arranged on the fourth active portion A4, and the fifth transistor TR5 may include a fifth active portion A5 and a fifth gate electrode GE5 arranged on the fifth active portion A5. The first, second, third, fourth, and fifth active portions A1, A2, A3, A4, and A5 may be included in the substrate SUB.

The first active portion A1 may include a first source region SR1, a first drain region DR1, and a first channel region CH1 between the first source region SR1 and the first drain region DR1. The second active portion A2 may include a second source region SR2, a second drain region DR2, and a second channel region CH2 between the second source region SR2 and the second drain region DR2. The third active portion A3 may include a third source region SR3, a third drain region DR3, and a third channel region CH3 between the third source region SR3 and the third drain region DR3. The fourth active portion A4 may include a fourth source region SR4, a fourth drain region DR4, and a fourth channel region CH4 between the fourth source region SR4 and the fourth drain region DR4. In addition, the fifth active portion A5 may include a fifth source region SR5, a fifth drain region DR5, and a fifth channel region CH5 between the fifth source region SR5 and the fifth drain region DR5. The first, second, third, fourth, and fifth source regions SR1, SR2, SR3, SR4, and SR5 may be source electrodes of the corresponding transistors TR1, TR2, TR3, TR4, and TR5, and the first, second, third, fourth, and fifth drain regions DR1, DR2, DR3, DR4, and DR5 may be drain electrodes of the corresponding transistors TR1, TR2, TR3, TR4, and TR5.

The body electrodes BE of the transistors TR1, TR2, TR3, TR4, and TR5 may be included in the substrate SUB. The body electrode BE may be arranged between the first source region SR1 of the first transistor TR1 and the fifth drain region DR5 of the fifth transistor TR5. The body electrode BE may receive a first power voltage (e.g., the first power voltage ELVDD) of FIG. 3.

The first gate electrode GE1 may overlap the first channel region CH1 of the first active portion A1 in plan view, the second gate electrode GE2 may overlap the second channel region CH2 of the second active portion A2 in plan view, the third gate electrode GE3 may overlap the third channel region CH3 of the third active portion A3 in plan view, the fourth gate electrode GE4 may overlap the fourth channel region CH4 of the fourth active portion A4 in plan view, and the fifth gate electrode GE5 may overlap the fifth channel region CH5 of the fifth active portion A5 in plan view.

For example, the first, second, third, fourth, and fifth source regions SR1, SR2, SR3, SR4, and SR5 and the first, second, third, fourth, and fifth drain regions DR1, DR2, DR3, DR4, and DR5 may be doped with an impurity (e.g., a p-type impurity).

In one or more embodiments, an element isolation film including an insulating material may be provided between the first, second, third, fourth, and fifth active portions A1, A2, A3, A4, and A5.

For example, the first, second, third, fourth, and fifth gate electrodes GE1, GE2, GE3, GE4, and GE5 may include a metal, a metal nitride, doped polysilicon, and/or the like. The first, second, third, fourth, and fifth gate electrodes GE1, GE2, GE3, GE4, and GE5 may include substantially the same material and may be arranged in substantially the same layer.

A gate-insulating layer (e.g., GI of FIG. 4) may be arranged between the first, second, third, fourth, and fifth gate electrodes GE1, GE2, GE3, GE4, and GE5 and the corresponding first to fifth channel regions CH1, CH2, CH3, CH4, and CH5. For example, the gate-insulating layer may include silicon oxide (e.g., SiO₂), silicon nitride, and/or an insulating material having a high dielectric constant.

Referring further to FIG. 7, the first metal layer ML1 may include the first, second, and third gate lines GWL, EBL, and ECL, the emission control line EML, first, second, third, and fourth source connection electrodes SCE1, SCE2, SCE3, and SCE4, second, third, fourth, and fifth drain connection electrodes DCE2, DCE3, DCE4, and DCE5, a gate connection electrode GCE, a source-drain connection electrode SDCE, and a first body connection electrode BCEa spaced and/or apart (e.g., spaced apart or separated) from each other.

As illustrated in FIGS. 15, 16, and 17, the first metal layer ML1 may be arranged on the first interlayer insulating layer VA1.

The first source connection electrode SCE1 may be connected to the first source region SR1 through first contact holes CT1 penetrating the first interlayer insulating layer VA1 (e.g., each of the first contact holes CT1 may be a through hole of the first interlayer insulating layer VA1). The source-drain connection electrode SDCE may be connected to the first drain region DR1 through second contact holes CT2 penetrating the first interlayer insulating layer VA1 (e.g., each of the second contact holes CT2 may be a through hole of the first interlayer insulating layer VA1), and may be connected to the fifth source region SR5 through tenth contact holes CT10 penetrating the first interlayer insulating layer VA1 (e.g., each of the tenth contact holes CT10 may be a through hole of the first interlayer insulating layer VA1). Accordingly, the source-drain connection electrode SDCE may electrically connect the first transistor TR1 and the fifth transistor TR5. The gate connection electrode GCE may be connected to the first gate electrode GE1 through third contact holes CT3 penetrating the first interlayer insulating layer VA1 (e.g., each of the third contact holes CT3 may be a through hole of the first interlayer insulating layer VA1).

The second source connection electrode SCE2 may be connected to the second source region SR2 through fourth contact holes CT4 penetrating the first interlayer insulating layer VA1 (e.g., each of the fourth contact holes CT4 may be a through hole of the first interlayer insulating layer VA1). The second drain connection electrode DCE2 may be connected to the second drain region DR2 through fifth contact holes CT5 penetrating the first interlayer insulating layer VA1 (e.g., each of the fifth contact holes CT5 may be a through hole of the first interlayer insulating layer VA1).

The third source connection electrode SCE3 may be connected to the third source region SR3 through sixth contact holes CT6 penetrating the first interlayer insulating layer VA1 (e.g., each of the sixth contact holes CT6 may be a through hole of the first interlayer insulating layer VA1). The third drain connection electrode DCE3 may be connected to the third drain region DR3 through seventh contact holes CT7 penetrating the first interlayer insulating layer VA1 (e.g., each of the seventh contact holes CT7 may be a through hole of the first interlayer insulating layer VA1).

The fourth source connection electrode SCE4 may be connected to the fourth source region SR4 through eighth contact holes CT8 penetrating the first interlayer insulating layer VA1 (e.g., each of the eighth contact holes CT8 may be a through hole of the first interlayer insulating layer VA1). The fourth drain connection electrode DCE4 may be connected to the fourth drain region DR4 through ninth contact holes CT9 penetrating the first interlayer insulating layer VA1 (e.g., each of the ninth contact holes CT9 may be a through hole of the first interlayer insulating layer VA1).

The fifth drain connection electrode DCE5 may be connected to the fifth drain region DR5 through eleventh contact holes CT11 penetrating the first interlayer insulating layer VA1 (e.g., each of the eleventh contact holes CT11 may be a through hole of the first interlayer insulating layer VA1).

The first gate line GWL may be to extend in the first direction D1. The first gate line GWL may be connected to the second gate electrode GE2 through twelfth contact holes CT12 penetrating the first interlayer insulating layer VA1 (e.g., each of the twelfth contact holes CT12 may be a through hole of the first interlayer insulating layer VA1). The first gate line GWL may receive a first gate signal (e.g., the first gate signal GW of FIG. 3). Accordingly, the second gate electrode GE2 may receive the first gate signal through the first gate line GWL.

The emission control line EML may be to extend in the first direction D1. The emission control line EML may be connected to the third gate electrode GE3 through thirteenth contact holes CT13 penetrating the first interlayer insulating layer VA1 (e.g., each of the thirteenth contact holes CT13 may be a through hole of the first interlayer insulating layer VA1). The emission control line EML may receive an emission control signal (e.g., the emission control signals EM of FIG. 3). Accordingly, the third gate electrode GE3 may receive the emission control signal through the emission control line EML.

The second gate line EBL may be to extend in the first direction D1. The second gate line EBL may be connected to the fourth gate electrode GE4 through fifteenth contact holes CT15 penetrating the first interlayer insulating layer VA1 (e.g., each of the fifteenth contact holes CT15 may be a through hole of the first interlayer insulating layer VA1). The second gate line EBL may receive a second gate signal (e.g., the second gate signal EB of FIG. 3). Accordingly, the fourth gate electrode GE4 may receive the second gate signal through the second gate line EBL.

The third gate line ECL may be to extend in the first direction D1. The third gate line ECL may be connected to the fifth gate electrode GE5 through fourteenth contact holes CT14 penetrating the first interlayer insulating layer VA1 (e.g., each of the fourteenth contact holes CT14 may be a through hole of the first interlayer insulating layer VA1). The third gate line ECL may receive a third gate signal (e.g., the third gate signal EC of FIG. 3). Accordingly, the fifth gate electrode GE5 may receive the third gate signal through the third gate line ECL.

The first body connection electrode BCEa may be connected to the body electrode BE through sixteenth contact holes CT16 penetrating the first interlayer insulating layer VA1 (e.g., each of the sixteenth contact holes CT16 may be a through hole of the first interlayer insulating layer VA1).

The first, second, and third gate lines GWL, EBL, and ECL, the emission control line EML, the first, second, third, and fourth source connection electrodes SCE1, SCE2, SCE3, and SCE4, the second, third, fourth, and fifth drain connection electrodes DCE2, DCE3, DCE4, and DCE5, the gate connection electrode GCE, the source-drain connection electrode SDCE, and the first body connection electrode BCEa may be arranged in the same layer and may include substantially the same material.

Referring further to FIG. 8, the second metal layer ML2 may include a first node electrode NE1, a second node electrode NE2, a third node electrode NE3, a first data connection electrode DCEa, the initialization line VIL, a first direct current voltage line ELVDL1, and a second body connection electrode BCEb spaced and/or apart (e.g., spaced apart or separated) from each other.

As illustrated in FIGS. 15, 16, and 17, the second interlayer insulating layer VA2 may be arranged on the first metal layer ML1, and the second metal layer ML2 may be arranged on the second interlayer insulating layer VA2.

The first node electrode NE1 may be to extend in the second direction D2. The first node electrode NE1 may be connected to the gate connection electrode GCE through seventeenth contact holes CT17 penetrating the second interlayer insulating layer VA2 (e.g., each of the seventeenth contact holes CT17 may be a through hole of the second interlayer insulating layer VA2).

The second node electrode NE2 may be to extend in the second direction D2. The second node electrode NE2 may be connected to the first source connection electrode SCE1 through eighteenth contact holes CT18 penetrating the second interlayer insulating layer VA2 (e.g., each of the eighteenth contact holes CT18 may be a through hole of the second interlayer insulating layer VA2), and may be connected to the third source connection electrode SCE3 through nineteenth contact holes CT19 penetrating the second interlayer insulating layer VA2 (e.g., each of the nineteenth contact holes CT19 may be a through hole of the second interlayer insulating layer VA2). Accordingly, the second node electrode NE2 may electrically connect the first transistor TR1 and the third transistor TR3.

The third node electrode NE3 may be connected to the fourth drain connection electrode DCE4 through twentieth contact holes CT20 penetrating the second interlayer insulating layer VA2 (e.g., each of the twentieth contact holes CT20 may be a through hole of the second interlayer insulating layer VA2), and may be connected to the fifth drain connection electrode DCE5 through twenty-first contact holes CT21 penetrating the second interlayer insulating layer VA2 (e.g., each of the twenty-first contact holes CT21 may be a through hole of the second interlayer insulating layer VA2). Accordingly, the third node electrode NE3 may electrically connect the fourth transistor TR4 and the fifth transistor TR5.

The initialization line VIL may be to extend in the second direction D2. The initialization line VIL may be connected to the fourth source connection electrode SCE4 through twenty-second contact holes CT22 penetrating the second interlayer insulating layer VA2 (e.g., each of the twenty-second contact holes CT22 may be a through hole of the second interlayer insulating layer VA2). The initialization line VIL may receive an initialization voltage (e.g., the initialization voltage VINT of FIG. 3). Accordingly, the fourth source connection electrode SCE4 may receive the initialization voltage through the initialization line VIL.

The first direct current voltage line ELVDL1 may be to extend in the second direction D2. The first direct current voltage line ELVDL1 may be connected to the third drain connection electrode DCE3 through twenty-third contact holes CT23 penetrating the second interlayer insulating layer VA2 (e.g., each of the twenty-third contact holes CT23 may be a through hole of the second interlayer insulating layer VA2). The first direct current voltage line ELVDL1 may receive a direct current voltage. Accordingly, the third drain connection electrode DCE3 may receive the direct current voltage through the first direct current voltage line ELVDL1. In one or more embodiments, the direct current voltage may be the first power voltage.

The second body connection electrode BCEb may be connected to the first body connection electrode BCEa through twenty-fourth contact holes CT24 penetrating the second interlayer insulating layer VA2 (e.g., each of the twenty-fourth contact holes CT24 may be a through hole of the second interlayer insulating layer VA2).

The first data connection electrode DCEa may be connected to the second source connection electrode SCE2 through twenty-fifth contact holes CT25 penetrating the second interlayer insulating layer VA2 (e.g., each of the twenty-fifth contact holes CT25 may be a through hole of the second interlayer insulating layer VA2).

The first node electrode NE1, the second node electrode NE2, the third node electrode NE3, the first data connection electrode DCEa, the initialization line VIL, the first direct current voltage line ELVDL1, and the second body connection electrode BCEb may be arranged in the same layer and may include substantially the same material.

Referring further to FIG. 9, the third metal layer ML3 may include a first-first capacitor electrode CPE1a, a first-second capacitor electrode CPE1b, a second data connection electrode DCEb, a first voltage connection electrode ECEa, a first pixel connection electrode PCEa, and/or an island pattern ISP spaced and/or apart (e.g., spaced apart or separated) from each other.

As illustrated in FIGS. 15, 16, and 17, the third interlayer insulating layer VA3 may be arranged on the second metal layer ML2, and the third metal layer ML3 may be arranged on the third interlayer insulating layer VA3.

In one or more embodiments, the first-first capacitor electrode CPE1a may include a first-first electrode stem portion ESP1a and a plurality of first-first electrode branch portions EBP1a extending in the second direction D2 from the first-first electrode stem portion ESP1a. The plurality of first-first electrode branch portions EBP1a may be spaced and/or apart (e.g., spaced apart or separated) from each other along the first direction D1. For example, the number of the plurality of first-first electrode branch portions EBP1a may be five, but one or more embodiments of the present disclosure are not limited thereto. The first-first electrode stem portion ESP1a of the first-first capacitor electrode CPE1a may be connected to the first node electrode NE1 through twenty-sixth contact holes CT26 penetrating the third interlayer insulating layer VA3 (e.g., each of the twenty-sixth contact holes CT26 may be a through hole of the third interlayer insulating layer VA3).

In one or more embodiments, the first-second capacitor electrode CPE1b may include a first-second electrode stem portion ESP1b and a plurality of first-second electrode branch portions EBP1b extending in a direction opposite to the second direction D2 from the first-second electrode stem portion ESP1b. The plurality of first-second electrode branch portions EBP1b may be spaced and/or apart (e.g., spaced apart or separated) from each other along the first direction D1. In addition, each of the plurality of first-second electrode branch portions EBP1b may be arranged between the plurality of first-first electrode branch portions EBP1a in plan view. For example, the number of the plurality of first-second electrode branch portions EBP1b may be four, but one or more embodiments of the present disclosure are not limited thereto. The first-second electrode stem portion ESP1b of the first-second capacitor electrode CPE1b may be connected to the second node electrode NE2 through twenty-seventh contact holes CT27 penetrating the third interlayer insulating layer VA3 (e.g., each of the twenty-seventh contact holes CT27 may be a through hole of the third interlayer insulating layer VA3).

In one or more embodiments, the first-first capacitor electrode CPE1a and the first-second capacitor electrode CPE1b may constitute a portion (e.g., a first sub-capacitor) of the capacitor CAP. The first-first capacitor electrode CPE1a may be a first electrode of the capacitor CAP, and the first-second capacitor electrode CPE1b may be a second electrode of the capacitor CAP.

The second data connection electrode DCEb may be connected to the first data connection electrode DCEa through twenty-eighth contact holes CT28 penetrating the third interlayer insulating layer VA3 (e.g., each of the twenty-eighth contact holes CT28 may be a through hole of the third interlayer insulating layer VA3).

The first voltage connection electrode ECEa may be connected to the first direct current voltage line ELVDL1 through twenty-ninth contact holes CT29 penetrating the third interlayer insulating layer VA3 (e.g., each of the twenty-ninth contact holes CT29 may be a through hole of the third interlayer insulating layer VA3).

The first pixel connection electrode PCEa may be connected to the third node electrode NE3 through thirtieth contact holes CT30 penetrating the third interlayer insulating layer VA3 (e.g., each of the thirtieth contact holes CT30 may be a through hole of the third interlayer insulating layer VA3).

The island pattern ISP may be connected to the first direct current voltage line ELVDL1 through thirty-first contact holes CT31 penetrating the third interlayer insulating layer VA3 (e.g., each of the thirty-first contact holes CT31 may be a through hole of the third interlayer insulating layer VA3).

The first-first capacitor electrode CPE1a, the first-second capacitor electrode CPE1b, the second data connection electrode DCEb, the first voltage connection electrode ECEa, the first pixel connection electrode PCEa, and the island pattern ISP may be arranged in the same layer and may include substantially the same material.

Referring further to FIG. 10, the fourth metal layer ML4 may include a second-first capacitor electrode CPE2a, a second-second capacitor electrode CPE2b, a third data connection electrode DCEc, a second voltage connection electrode ECEb, and a second pixel connection electrode PCEb spaced and/or apart (e.g., spaced apart or separated) from each other.

As illustrated in FIGS. 15, 16, and 17, the fourth interlayer insulating layer VA4 may be arranged on the third metal layer ML3, and the fourth metal layer ML4 may be arranged on the fourth interlayer insulating layer VA4.

In one or more embodiments, the second-first capacitor electrode CPE2a may include a second-first electrode stem portion ESP2a and a plurality of second-first electrode branch portions EBP2a extending in the second direction D2 from the second-first electrode stem portion ESP2a. The plurality of second-first electrode branch portions EBP2a may be spaced and/or apart (e.g., spaced apart or separated) from each other along the first direction D1. For example, the number of the plurality of second-first electrode branch portions EBP2a may be four, but one or more embodiments of the present disclosure are not limited thereto. The second-first electrode stem portion ESP2a of the second-first capacitor electrode CPE2a may be connected to the first-first electrode stem portion ESP1a of the first-first capacitor electrode CPE1a through thirty-second contact holes CT32 penetrating the fourth interlayer insulating layer VA4 (e.g., each of the thirty-second contact holes CT32 may be a through hole of the fourth interlayer insulating layer VA4).

In one or more embodiments, the second-second capacitor electrode CPE2b may include a second-second electrode stem portion ESP2b and a plurality of second-second electrode branch portions EBP2b extending in a direction opposite to the second direction D2 from the second-second electrode stem portion ESP2b. The plurality of second-second electrode branch portions EBP2b may be spaced and/or apart (e.g., spaced apart or separated) from each other along the first direction D1. In addition, each of the plurality of second-second electrode branch portions EBP2b may be arranged between the plurality of first-second electrode branch portions EBP2a in plan view. For example, the number of the plurality of second-second electrode branch portions EBP2b may be five, but one or more embodiments of the present disclosure are not limited thereto. The second-second electrode stem portion ESP2b of the second-second capacitor electrode CPE2b may be connected to the first-second electrode stem portion ESP1b of the first-second capacitor electrode CPE1b through thirty-third contact holes CT33 penetrating the fourth interlayer insulating layer VA4 (e.g., each of the thirty-third contact holes CT33 may be a through hole of the fourth interlayer insulating layer VA4).

In one or more embodiments, the second-first capacitor electrode CPE2a and the second-second capacitor electrode CPE2b may constitute a portion (e.g., a second sub-capacitor) of the capacitor CAP. The second-first capacitor electrode CPE2a may be a first electrode of the capacitor CAP, and the second-second capacitor electrode CPE2b may be a second electrode of the capacitor CAP.

In one or more embodiments, the second-first capacitor electrode CPE2a may overlap the first-first capacitor electrode CPE1a and the first-second capacitor electrode CPE1b in plan view, and the second-second capacitor electrode CPE2b may overlap the first-first capacitor electrode CPE1a and the first-second capacitor electrode CPE1b in plan view. For example, the second-first electrode stem portion ESP2a may overlap the first-first electrode stem portion ESP1a in plan view, and the plurality of second-first electrode branch portions EBP2a may overlap the plurality of first-second electrode branch portions EBP1b in plan view. In addition, the second-second electrode stem portion ESP2b may overlap the first-second electrode stem portion ESP1b in plan view, and the plurality of second-second electrode branch portions EBP2b may overlap the plurality of first-first electrode branch portions EBP1a in plan view. Accordingly, the second-first capacitor electrode CPE2a and the first-second capacitor electrode CPE1b may constitute a portion (e.g., a third sub-capacitor) of the capacitor CAP, and the second-second capacitor electrode CPE2b and the first-first capacitor electrode CPE1a may constitute a portion (e.g., a fourth sub-capacitor) of the capacitor CAP.

The third data connection electrode DCEc may be connected to the second data connection electrode DCEb through thirty-fourth contact holes CT34 penetrating the fourth interlayer insulating layer VA4 (e.g., each of the thirty-fourth contact holes CT34 may be a through hole of the fourth interlayer insulating layer VA4).

The second voltage connection electrode ECEb may be connected to the first voltage connection electrode ECEa through thirty-fifth contact holes CT35 penetrating the fourth interlayer insulating layer VA4 (e.g., each of the thirty-fifth contact holes CT35 may be a through hole of the fourth interlayer insulating layer VA4).

The second pixel connection electrode PCEb may be connected to the first pixel connection electrode PCEa through thirty-sixth contact holes CT36 penetrating the fourth interlayer insulating layer VA4 (e.g., each of the thirty-sixth contact holes CT36 may be a through hole of the fourth interlayer insulating layer VA4).

The second-first capacitor electrode CPE2a, the second-second capacitor electrode CPE2b, the third data connection electrode DCEc, the second voltage connection electrode ECEb, and the second pixel connection electrode PCEb may be arranged in substantially the same layer and may include substantially the same material.

Referring further to FIG. 11, the fifth metal layer ML5 may include a third-first capacitor electrode CPE3a, a third-second capacitor electrode CPE3b, a fourth data connection electrode DCEd, a third voltage connection electrode ECEc, and a third pixel connection electrode PCEc spaced and/or apart (e.g., spaced apart or separated) from each other.

As illustrated in FIGS. 15, 16, and 17, the fifth interlayer insulating layer VA5 may be arranged on the fourth metal layer ML4, and the fifth metal layer ML5 may be arranged on the fifth interlayer insulating layer VA5.

In one or more embodiments, the third-first capacitor electrode CPE3a may include a third-first electrode stem portion ESP3a and a plurality of third-first electrode branch portions EBP3a extending in the second direction D2 from the third-first electrode stem portion ESP3a. The plurality of third-first electrode branch portions EBP3a may be spaced and/or apart (e.g., spaced apart or separated) from each other along the first direction D1. For example, the number of the plurality of third-first electrode branch portions EBP3a may be five, but one or more embodiments of the present disclosure are not limited thereto. The third-first electrode stem portion ESP3a of the third-first capacitor electrode CPE3a may be connected to the second-first electrode stem portion ESP2a of the second-first capacitor electrode CPE2a through a thirty-seventh contact hole CT37 penetrating the fifth interlayer insulating layer VA5 (e.g., each of the thirty-seventh contact holes CT37 may be a through hole of the fifth interlayer insulating layer VA5).

In one or more embodiments, the third-second capacitor electrode CPE3b may include a third-second electrode stem portion ESP3b and a plurality of third-second electrode branch portions EBP3b extending in a direction opposite to the second direction D2 from the third-second electrode stem portion ESP3b. The plurality of third-second electrode branch portions EBP3b may be spaced and/or apart (e.g., spaced apart or separated) from each other along the first direction D1. In addition, each of the plurality of third-second electrode branch portions EBP3b may be arranged between the plurality of third-first electrode branch portions EBP3a in plan view. For example, the number of the plurality of third-second electrode branch portions EBP3b may be four, but one or more embodiments of the present disclosure are not limited thereto. The third-second electrode stem portion ESP3b of the third-second capacitor electrode CPE3b may be connected to the second-second electrode stem portion ESP2b of the second-second capacitor electrode CPE2b through a thirty-eighth contact hole CT38 penetrating the fifth interlayer insulating layer VA5 (e.g., each of the thirty-eighth contact hole CT38 may be a through hole of the fifth interlayer insulating layer VA5).

In one or more embodiments, the third-first capacitor electrode CPE3a and the third-second capacitor electrode CPE3b may together constitute a portion (e.g., a fifth sub-capacitor) of the capacitor CAP. The third-first capacitor electrode CPE3a may be a first electrode of the capacitor CAP, and the third-second capacitor electrode CPE3b may be a second electrode of the capacitor CAP.

In one or more embodiments, the third-first capacitor electrode CPE3a may overlap the second-first capacitor electrode CPE2a and the second-second capacitor electrode CPE2b in plan view, and the third-second capacitor electrode CPE3b may overlap the second-first capacitor electrode CPE2a and the second-second capacitor electrode CPE2b in plan view. For example, the third-first electrode stem part ESP3a may overlap the second-first electrode stem portion ESP2a in plan view, and the plurality of third-first electrode branch portions EBP3a may overlap the plurality of second-second electrode branch portions EBP2b in plan view. In addition, the third-second electrode stem portion ESP3b may overlap the second-second electrode stem portion ESP2b in plan view, and the plurality of third-second electrode branch portions EBP3b may overlap the plurality of second-first electrode branch portions EBP2a in plan view. Accordingly, the third-first capacitor electrode CPE3a and the second-second capacitor electrode CPE2b may constitute a portion (e.g., a sixth sub-capacitor) of the capacitor CAP, and the third-second capacitor electrode CPE3b and the second-first capacitor electrode CPE2a may constitute a portion (e.g., a seventh sub-capacitor) of the capacitor CAP.

The fourth data connection electrode DCEd may be connected to the third data connection electrode DCEc through thirty-ninth contact holes CT39 penetrating the fifth interlayer insulating layer VA5 (e.g., each of the thirty-ninth contact holes CT39 may be a through hole of the fifth interlayer insulating layer VA5).

The third voltage connection electrode ECEc may be connected to the second voltage connection electrode ECEb through fortieth contact holes CT40 penetrating the fifth interlayer insulating layer VA5 (e.g., each of the fortieth contact holes CT40 may be a through hole of the fifth interlayer insulating layer VA5).

The third pixel connection electrode PCEc may be connected to the second pixel connection electrode PCEb through forty-first contact holes CT41 penetrating the fifth interlayer insulating layer VA5 (e.g., each of the forty-first contact holes CT41 may be a through hole of the fifth interlayer insulating layer VA5).

The third-first capacitor electrode CPE3a, the third-second capacitor electrode CPE3b, the fourth data connection electrode DCEd, the third voltage connection electrode ECEc, and the third pixel connection electrode PCEc may be arranged in substantially the same layer and may include substantially the same material.

Referring further to FIG. 12, the sixth metal layer ML6 may include a fourth-first capacitor electrode CPE4a, a fourth-second capacitor electrode CPE4b, a fifth data connection electrode DCEe, a fourth voltage connection electrode ECEd, and a fourth pixel connection electrode PCEd spaced and/or apart (e.g., spaced apart or separated) from each other.

As illustrated in FIGS. 15, 16, and 17, the sixth interlayer insulating layer VA6 may be arranged on the fifth metal layer ML5, and the sixth metal layer ML6 may be arranged on the sixth interlayer insulating layer VA6.

In one or more embodiments, the fourth-first capacitor electrode CPE4a may include a fourth-first electrode stem portion ESP4a and a plurality of fourth-first electrode branch portions EBP4a extending from the fourth-first electrode stem portion ESP4a in the second direction D2. The plurality of fourth-first electrode branch portions EBP4a may be spaced and/or apart (e.g., spaced apart or separated) from each other along the first direction D1. For example, the number of the plurality of fourth-first electrode branch portions EBP4a may be four, but one or more embodiments of the present disclosure are not limited thereto. The fourth-first electrode stem portion ESP4a of the fourth-first capacitor electrode CPE4a may be connected to the third-first electrode stem portion ESP3a of the third-first capacitor electrode CPE3a through forty-two contact holes CT42 penetrating the sixth interlayer insulating layer VA6 (e.g., each of the forty-two contact holes CT42 may be a through hole of the sixth interlayer insulating layer VA6).

In one or more embodiments, the fourth-second capacitor electrode CPE4b may include a fourth-second electrode stem portion ESP4b and a plurality of fourth-second electrode branch portions EBP4b extending from the fourth-second electrode stem portion ESP4b in a direction opposite to the second direction D2. The plurality of fourth-second electrode branch portions EBP4b may be spaced and/or apart (e.g., spaced apart or separated) from each other along the first direction D1. In addition, each of the plurality of fourth-second electrode branch portions EBP4b may be arranged between the plurality of fourth-first electrode branch portions EBP4a in plan view. For example, the number of the plurality of fourth-second electrode branch portions EBP4b may be five, but one or more embodiments of the present disclosure are not limited thereto. The fourth-second electrode stem portion ESP4b of the fourth-second capacitor electrode CPE4b may be connected to the third-second electrode stem portion ESP3b of the third-second capacitor electrode CPE3b through forty-three contact holes CT43 penetrating the sixth interlayer insulating layer VA6 (e.g., each of the forty-three contact holes CT43 may be a through hole of the sixth interlayer insulating layer VA6).

In one or more embodiments, the fourth-first capacitor electrode CPE4a and the fourth-second capacitor electrode CPE4b may constitute a portion (e.g., an eighth sub-capacitor) of the capacitor CAP. The fourth-first capacitor electrode CPE4a may be a first electrode of the capacitor CAP, and the fourth-second capacitor electrode CPE4b may be a second electrode of the capacitor CAP.

In one or more embodiments, the fourth-first capacitor electrode CPE4a may overlap the third-first capacitor electrode CPE3a and the third-second capacitor electrode CPE3b in plan view, and the fourth-second capacitor electrode CPE4b may overlap the third-first capacitor electrode CPE3a and the third-second capacitor electrode CPE3b in plan view. For example, the fourth-first electrode stem portion ESP4a may overlap the third-first electrode stem portion ESP3a in plan view, and the plurality of fourth-first electrode branch portions EBP4a may overlap the plurality of third-second electrode branch portions EBP3b in plan view. In addition, the fourth-second electrode stem portion ESP4b may overlap the third-second electrode stem portion ESP3b in plan view, and the plurality of fourth-second electrode branch portions EBP4b may overlap the plurality of third-first electrode branch portions EBP3a in plan view. Accordingly, the fourth-first capacitor electrode CPE4a and the third-second capacitor electrode CPE3b may constitute a portion (e.g., a ninth sub-capacitor) of the capacitor CAP, and the fourth-second capacitor electrode CPE4b and the third-first capacitor electrode CPE3a may constitute a portion (e.g., a tenth sub-capacitor) of the capacitor CAP.

As a result, the first, second, third, fourth, fifth, sixth, seventh, eighth, ninth, and tenth sub-capacitors may be connected in parallel to each other. Accordingly, the first-first, second-first, third-first, and fourth-first capacitor electrodes CPE1a, CPE2a, CPE3a, and CPE4a may be the first electrode of the capacitor CAP, and the first-second, second-second, third-second, and fourth-second capacitor electrodes CPE1b, CPE2b, CPE3b, and CPE4b may be the second electrode of the capacitor CAP.

As described above, the first-first capacitor electrode CPE1a, the second-second capacitor electrode CPE2b, the third-first capacitor electrode CPE3a, and the fourth-second capacitor electrode CPE4b may overlap with each other in plan view, and the first-second capacitor electrode CPE1b, the second-first capacitor electrode CPE2a, the third-second capacitor electrode CPE3b, and the fourth-first capacitor electrode CPE4a may overlap with each other in plan view. Accordingly, the capacitance of the capacitor CAP may be improved or maximized/optimized.

The fifth data connection electrode DCEe may be connected to the fourth data connection electrode DCEd through forty-four contact holes CT44 penetrating the sixth interlayer insulating layer VA6 (e.g., each of the forty-four contact holes CT44 may be a through hole of the sixth interlayer insulating layer VA6).

The fourth voltage connection electrode ECEd may be connected to the third voltage connection electrode ECEc through forty-five contact holes CT45 penetrating the sixth interlayer insulating layer VA6 (e.g., each of the forty-five contact holes CT45 may be a through hole of the sixth interlayer insulating layer VA6).

The fourth pixel connection electrode PCEd may be connected to the third pixel connection electrode PCEc through forty-six contact holes CT46 penetrating the sixth interlayer insulating layer VA6 (e.g., each of the forty-six contact holes CT46 may be a through hole of the sixth interlayer insulating layer VA6).

The fourth-first capacitor electrode CPE4a, the fourth-second capacitor electrode CPE4b, the fifth data connection electrode DCEe, the fourth voltage connection electrode ECEd, and the fourth pixel connection electrode PCEd may be arranged in the same layer and may include substantially the same material.

Referring further to FIG. 13, the seventh metal layer ML7 may include a sixth data connection electrode DCEf, a second direct current voltage line ELVDL2, and/or a fifth pixel connection electrode PCEe spaced and/or apart (e.g., spaced apart or separated) from each other.

As illustrated in FIGS. 15, 16, and 17, the seventh interlayer insulating layer VA7 may be arranged on the sixth metal layer ML6, and the seventh metal layer ML7 may be arranged on the seventh interlayer insulating layer VA7.

The sixth data connection electrode DCEf may be connected to the fifth data connection electrode DCEe through forty-seven contact holes CT47 penetrating the seventh interlayer insulating layer VA7 (e.g., each of the forty-seven contact holes CT47 may be a through hole of the seventh interlayer insulating layer VA7).

The second direct current voltage line ELVDL2 may be to extend in the second direction D2. The second direct current voltage line ELVDL2 may be connected to the fourth voltage connection electrode ECEd through forty-eight contact holes CT48 penetrating the seventh interlayer insulating layer VA7 (e.g., each of the forty-eight contact holes CT48 may be a through hole of the seventh interlayer insulating layer VA7). The second direct current voltage line ELVDL2 may receive a direct current voltage. In one or more embodiments, the direct current voltage may be the first power voltage (e.g., the first power voltage ELVDD of FIG. 3). In this case, the first direct current voltage line ELVDL1 and the second direct current voltage line ELVDL2 may be included in the first power line ELVDL of FIG. 3, and the first direct current voltage line ELVDL1 and the first, second, third, and fourth voltage connection electrodes ECEa, ECEb, ECEc, and ECEd may receive the direct current voltage through the second direct current voltage line ELVDL2. However, one or more embodiments of the present disclosure are not limited thereto. In one or more other embodiments, the direct current voltage may be an initialization voltage (e.g., the initialization voltage VINT of FIG. 3). In this case, the first, second, third, and fourth voltage connection electrodes ECEa, ECEb, ECEc, and ECEd may be electrically connected to the initialization line VIL.

In one or more embodiments, the second direct current voltage line ELVDL2 may have a mesh shape in plan view. However, one or more embodiments of the present disclosure are not limited thereto.

The fifth pixel connection electrode PCEe may be connected to the fourth pixel connection electrode PCEd through forty-nine contact holes CT49 penetrating the seventh interlayer insulating layer VA7 (e.g., each of the forty-nine contact holes CT49 may be a through hole of the seventh interlayer insulating layer VA7). The fifth pixel connection electrode PCEe may correspond to the pixel connection electrode PCE of FIG. 4.

In one or more embodiments, a thickness (e.g., a length in the third direction D3) of the seventh metal layer ML7 may be greater than a thickness (e.g., a length in the third direction D3) of each of the first, second, third, fourth, fifth, and sixth metal layers ML1, ML2, ML3, ML4, ML5, and ML6.

The sixth data connection electrode DCEf, the second direct current voltage line ELVDL2, and the fifth pixel connection electrode PCEe may be arranged in the same layer and may include substantially the same material.

Referring further to FIG. 14, the eighth metal layer ML8 may include the data line DL and a sixth pixel connection electrode PCEf spaced and/or apart (e.g., spaced apart or separated) from each other.

As illustrated in FIGS. 15, 16, and 17, the eighth interlayer insulating layer VA8 may be arranged on the seventh metal layer ML7, and the eighth metal layer ML8 may be arranged on the eighth interlayer insulating layer VA8.

The data line DL may be to extend in the second direction D2. The data line DL may be connected to the sixth data connection electrode DCEf through fifty contact holes CT50 penetrating the eighth interlayer insulating layer VA8 (e.g., each of the fifty contact holes CT50 may be a through hole of the eighth interlayer insulating layer VA8). In addition, the data line DL may receive a data voltage (e.g., the data voltage VDATA of FIG. 3). Accordingly, the first, second, third, fourth, fifth, and sixth data connection electrodes DCEa, DCEb, DCEc, DCEd, DCEe, and DCEf may receive the data voltage through the data line DL.

The data line DL may overlap the capacitor CAP and the second direct current voltage line ELVDL2 in plan view. In one or more embodiments, a portion of the data line DL overlapping the capacitor CAP may be covered (e.g., substantially or entirely covereds) by the second direct current voltage line ELVDL2. For example, a first width W1 of the second direct current voltage line ELVDL2 in the first direction D1 may be equal to or greater than a second width W2 of the data line DL in the first direction D1. Accordingly, the second direct current voltage line ELVDL2 may shield the formation of a coupling capacitor between the data line DL and the first electrode of the capacitor CAP.

In one or more embodiments, the forty-eight contact holes CT48 and the fifty contact holes CT50 may not be located on substantially the same straight line extending in the second direction D2. For example, the data line DL may include a first portion directly connected to the sixth data connection electrode DCEf and extending in the first direction D1, and a second portion extending in the second direction D2 and covering the fourth voltage connection electrode ECEd.

The sixth pixel connection electrode PCEf may be connected to the fifth pixel connection electrode PCEe through fifty-one contact holes CT51 penetrating the eighth interlayer insulating layer VA8 (e.g., each of the fifty-one contact holes CT51 may be a through hole of the eighth interlayer insulating layer VA8).

In one or more embodiments, a thickness (e.g., a length in the third direction D3) of the eighth metal layer ML8 may be greater than a thickness (e.g., a length in the third direction D3) of each of the first, second, third, fourth, fifth, and sixth metal layers ML1, ML2, ML3, ML4, ML5, and ML6. For example, the thickness of the data line DL may be greater than the thickness (e.g., the length in the third direction D3) of each of the first, second, third, fourth, fifth, and sixth metal layers ML1, ML2, ML3, ML4, ML5, and ML6. Accordingly, the resistance of the data line DL may be reduced or minimized.

The data line DL and the sixth pixel connection electrode PCEf may be arranged in substantially the same layer and may include substantially the same material.

As illustrated in FIGS. 15, 16, and 17, the passivation layer PAS may be arranged on the eighth metal layer ML8. A pixel electrode (e.g., PE1, PE2, or PE3 of FIG. 4), a light-emitting layer (e.g., EL of FIG. 4), and a common electrode (e.g., CE of FIG. 4) may be sequentially arranged on the passivation layer PAS. The pixel electrode may be electrically connected to the sixth pixel connection electrode PCEf through a contact hole. For example, the pixel electrode may be directly connected to the sixth pixel connection electrode PCEf. Alternatively, the pixel electrode may be connected to the sixth pixel connection electrode PCEf through a reflective electrode.

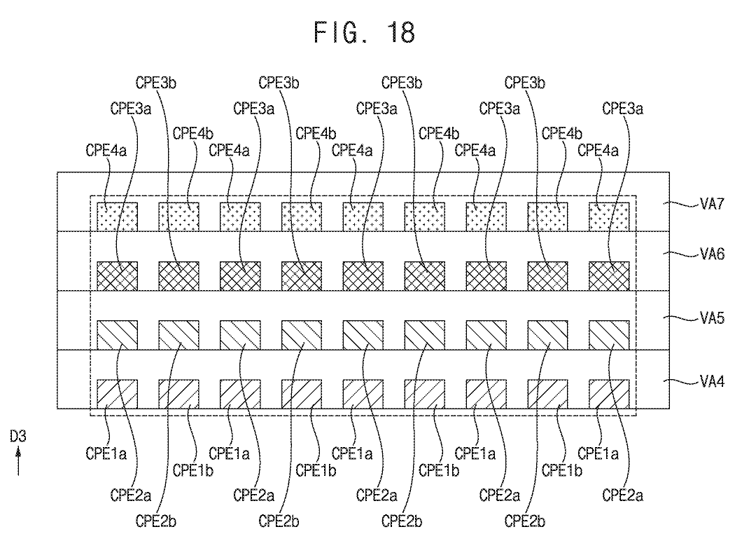

FIG. 18 is a cross-sectional view illustrating an example of a capacitor of FIG. 15.

Referring to FIG. 18, the plane shapes of the first-first and first-second capacitor electrodes CPE1a and CPE1b, the second-first and second-second capacitor electrodes CPE2a and CPE2b, the third-first and third-second capacitor electrodes CPE3a and CPE3b, and the fourth-first and fourth-second capacitor electrodes CPE4a and CPE4b may be substantially the same as the plane shapes of the first-first and first-second capacitor electrodes CPE1a and CPE1b, the second-first and second-second capacitor electrodes CPE2a and CPE2b, the third-first and third-second capacitor electrodes CPE3a and CPE3b, and the fourth-first and fourth-second capacitor electrodes CPE4a and CPE4b of FIGS. 9 to 12, respectively. In addition, the connection manner of the first-first, second-first, third-first, and fourth-first capacitor electrodes CPE1a, CPE2a, CPE3a, and CPE4a may be substantially the same as the connection manner of FIGS. 9, 10, 11, and 12, and the connection manner of the first-second, second-second, third-second, and fourth-second capacitor electrodes CPE1b, CPE2b, CPE3b, and CPE4b may be substantially the same as the connection manner of FIGS. 9, 10, 11, and 12.

The first-first capacitor electrode CPE1a and the first-second capacitor electrode CPE1b may constitute a portion (e.g., a first sub-capacitor) of the capacitor CAP, the second-first capacitor electrode CPE2a and the second-second capacitor electrode CPE2b may constitute a portion (e.g., a second sub-capacitor) of the capacitor CAP, the third-first capacitor electrode CPE3a and the third-second capacitor electrode CPE3b may constitute a portion (e.g., a third sub-capacitor) of the capacitor CAP, and the fourth-first capacitor electrode CPE4a and the fourth-second capacitor electrode CPE4b may constitute a portion (e.g., a fourth sub-capacitor) of the capacitor CAP.

In one or more embodiments, the first-first capacitor electrode CPE1a, the second-first capacitor electrode CPE2a, the third-first capacitor electrode CPE3a, and the fourth-first capacitor electrode CPE4a may overlap with each other in plan view, and the first-second capacitor electrode CPE1b, the second-second capacitor electrode CPE2b, the third-second capacitor electrode CPE3b, and the fourth-second capacitor electrode CPE4b may overlap with each other in plan view.

In one or more embodiments, the electrode branch portions (e.g., EBP1a, EBP2a, EBP3a, and EBP4a of FIGS. 9, 10, 11, and 12) of the first-first capacitor electrode CPE1a, the second-first capacitor electrode CPE2a, the third-first capacitor electrode CPE3a, and the fourth-first capacitor electrode CPE4a may be connected to each other through contact holes, and the electrode branch portions (e.g., EBP1b, EBP2b, EBP3b, and EBP4b of FIGS. 9, 10, 11, and 12) of the first-second capacitor electrode CPE1b, the second-second capacitor electrode CPE2b, the third-second capacitor electrode CPE3b, and the fourth-second capacitor electrode CPE4b may be connected to each other through contact holes, but one or more embodiments of the present disclosure are not limited thereto.

As a result, the first, second, third, and fourth sub-capacitors may be connected in parallel to each other. Accordingly, the first-first, second-first, third-first, and fourth-first capacitor electrodes CPE1a, CPE2a, CPE3a, and CPE4a may be the first electrode of the capacitor CAP, and the first-second, second-second, third-second, and fourth-second capacitor electrodes CPE1b, CPE2b, CPE3b, and CPE4b may be the second electrode of the capacitor CAP.

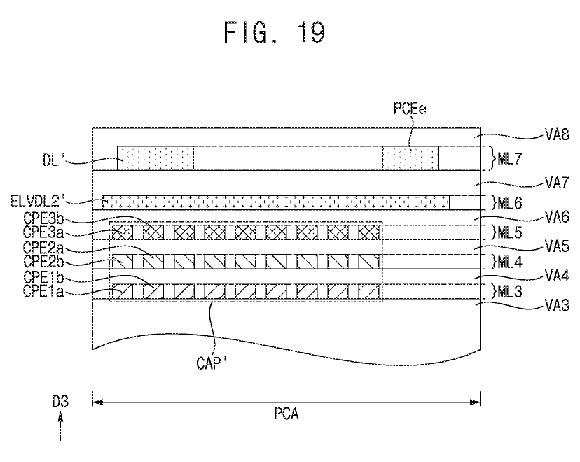

FIG. 19 is a cross-sectional view illustrating an example of third, fourth, fifth, sixth, and seventh metal layers of FIG. 15.

Referring to FIG. 19, the one or more embodiments described with reference to FIG. 19 may be substantially the same as or similar to the one or more embodiments described with reference to FIGS. 6 to 17, except for the structure of a capacitor CAP′, the position of a second direct-current voltage line ELVDL2′, the position of a data line DL′, and the omission of the eighth metal layer ML8. Hereinafter, overlapping descriptions may not be repeated here or may be simplified. However, for simplification of the drawings, FIG. 19 illustrates only the components arranged on the third interlayer insulating layer VA3.

Referring to FIG. 19, in one or more embodiments, the capacitor CAP′ may be composed of three metal layers. For example, the capacitor CAP′ may have a structure in which the fourth-first capacitor electrode CPE4a and the fourth-second capacitor electrode CPE4b may not be repeated from the capacitor CAP illustrated in FIGS. 9, 10, 11, and 12. In other words, the first-first, second-first, and third-first capacitor electrodes CPE1a, CPE2a, and CPE3a may be the first electrode of the capacitor CAP', and the first-second, second-second, and third-second capacitor electrodes CPE1b, CPE2b, and CPE3b may be the second electrode of the capacitor CAP'.

In one or more embodiments, the first-first capacitor electrode CPE1a, the second-second capacitor electrode CPE2b, and the third-first capacitor electrode CPE3a may overlap with each other in plan view, and the first-second capacitor electrode CPE1b, the second-first capacitor electrode CPE2a, and the third-second capacitor electrode CPE3b may overlap with each other in plan view. Accordingly, the first-first capacitor electrode CPE1a, the second-second capacitor electrode CPE2b, and the third-first capacitor electrode CPE3a may constitute a portion of the capacitor CAP′, and the first-second capacitor electrode CPE1b, the second-first capacitor electrode CPE2a, and the third-second capacitor electrode CPE3b may constitute a portion of the capacitor CAP′.

However, one or more embodiments of the present disclosure are not limited thereto. In one or more embodiments, as illustrated in FIG. 18, the first-first capacitor electrode CPE1a, the second-first capacitor electrode CPE2a, and the third-first capacitor electrode CPE3a may overlap each other in plan view, and the first-second capacitor electrode CPE1b, the second-second capacitor electrode CPE2b, and the third-second capacitor electrode CPE3b may overlap with each other in plan view.

In one or more embodiments, the electrode branch portions (e.g., EBP1a, EBP2a, and EBP3a of FIGS. 9, 10, and 11) of the first-first capacitor electrode CPE1a, the second-first capacitor electrode CPE2a, and the third-first capacitor electrode CPE3a may be connected to each other through contact holes, and the electrode branch portions (e.g., EBP1b, EBP2b, and EBP3b of FIGS. 9, 10, and 11) of the first-second capacitor electrode CPE1b, the second-second capacitor electrode CPE2b, and the third-second capacitor electrode CPE3b may be connected to each other through contact holes, but one or more embodiments of the present disclosure are not limited thereto.

In one or more embodiments, the second direct-current voltage line ELVDL2′ may be included in the sixth metal layer ML6. For example, the second direct-current voltage line ELVDL2′ may be arranged between the sixth interlayer insulating layer VA6 and the seventh interlayer insulating layer VA7. In this case, the fourth voltage connection electrode ECEd of FIGS. 12 and 17 may not be repeated here, and the second direct-current voltage line ELVDL2′ may be electrically connected to the first, second, and third voltage connection electrodes ECEa, ECEb, and ECEc of FIG. 17.

The second direct-current voltage line ELVDL2′ may receive a direct current voltage. For example, the direct current voltage may be a first power voltage (e.g., the first power voltage ELVDD of FIG. 3). Alternatively, the direct current voltage may be an initialization voltage (e.g., the initialization voltage VINT of FIG. 3). In this case, the second direct-current voltage line ELVDL2′ and the first, second and third voltage connection electrodes ECEa, ECEb, and ECEc of FIG. 17 may be electrically connected to the initialization line VIL of FIG. 8.

In one or more embodiments, the data line DL′ may be included in the seventh metal layer ML7. For example, the data line DL′ may be arranged between the seventh interlayer insulating layer VA7 and the eighth interlayer insulating layer VA8. In other words, the thickness of the data line DL′ may be greater than the thickness of the second direct current voltage line ELVDL2′. In this case, the sixth data connection electrode DCEf of FIG. 13 may not be repeated here, and the data line DL′ may be electrically connected to the first to fifth data connection electrodes DCEa, DCEb, DCEc, DCEd, and DCEe of FIGS. 8, 9, 10, 11, and 12.

The data line DL′ may overlap the second direct current voltage line ELVDL2′ in plan view. In one or more embodiments, the portion of the data line DL′ overlapping the capacitor CAP′ may be covered (e.g., substantially or entirely) by the second direct-current voltage line ELVDL2′. Accordingly, the second direct current voltage line ELVDL2′ may shield the formation of a coupling capacitor between the data line DL′ and the first electrode of the capacitor CAP′.

A pixel electrode (e.g., PE1, PE2, or PE3 of FIG. 4), a light-emitting layer (e.g., EL of FIG. 4), and a common electrode (e.g., CE of FIG. 4) may be sequentially arranged on the eighth interlayer insulating layer VA8. The pixel electrode may be electrically connected to the fifth pixel connection electrode PCEe through a contact hole. For example, the pixel electrode may be directly connected to the fifth pixel connection electrode PCEe, or may be connected to the fifth pixel connection electrode PCEe through a reflective electrode.

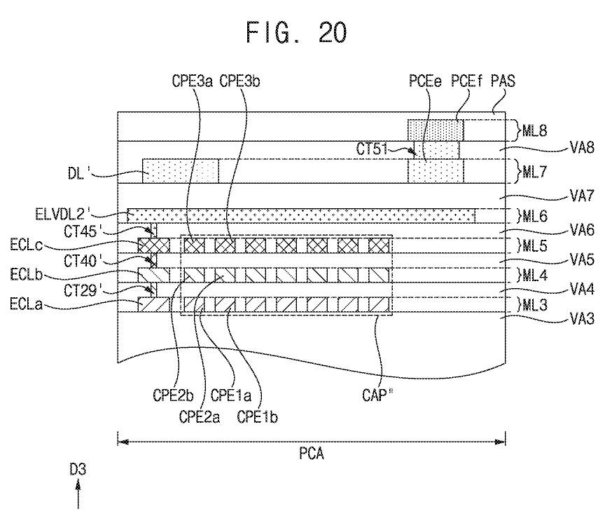

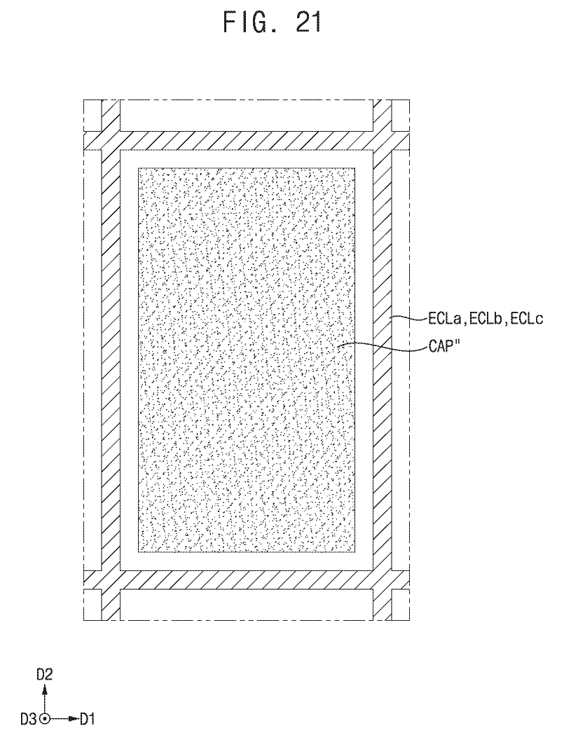

FIG. 20 is a cross-sectional view illustrating an example of third, fourth, fifth, sixth, seventh, and eighth metal layers of FIG. 15. FIG. 21 is a plan view illustrating a capacitor and voltage connection lines of FIG. 20.

Referring to FIGS. 20 and 21, the one or more embodiments described with reference to FIGS. 20 and 21 may be substantially the same as or similar to the one or more embodiments described with reference to FIG. 19, except for a capacitor CAP″, and the addition of the first, second, and third voltage connection lines ECLa, ECLb, and ECLc, and the eighth metal layer ML8. Hereinafter, overlapping descriptions may not be repeated or simplified. However, for simplification of the drawings, FIG. 20 illustrates only the components arranged on the third interlayer insulating layer VA3.

Referring to FIGS. 20 and 21, in one or more embodiments, the capacitor CAP″ may be composed of three metal layers. For example, the capacitor CAP″ may have a structure in which the fourth-first capacitor electrode CPE4a and the fourth-second capacitor electrode CPE4b may not be repeated from the capacitor CAP illustrated in FIGS. 9, 10, 11, and 12. The capacitor CAP″ may have fewer electrode branch portions compared to the capacitor CAP of FIG. 15 and the capacitor CAP′ of FIG. 19.

The first voltage connection line ECLa may be included in the third metal layer ML3, the second voltage connection line ECLb may be included in the fourth metal layer ML4, and the third voltage connection line ECLc may be included in the fifth metal layer ML5. In one or more embodiments, the second voltage connection line ECLb may be connected to the first voltage connection line ECLa through a twenty-ninth contact hole CT29′ penetrating the fourth interlayer insulating layer VA4 (e.g., each of the twenty-ninth contact holes CT29' may be a through hole of the fourth interlayer insulating layer VA4), and the third voltage connection line ECLc may be connected to the second voltage connection line ECLb through a fortieth contact hole CT40′ penetrating the fifth interlayer insulating layer VA5 (e.g., each of the fortieth contact holes CT40' may be a through hole of the fifth interlayer insulating layer VA5). In addition, the second direct current voltage line ELVDL2′ may be connected to the third voltage connection line ECLc through a forty-five contact hole CT45′ penetrating the sixth interlayer insulating layer VA6 (e.g., each of the forty-five contact holes CT45' may be a through hole of the sixth interlayer insulating layer VA6).

In one or more embodiments, as illustrated in FIG. 21, the first, second, and third voltage connection lines ECLa, ECLb, and ECLc may surround the capacitor CAP'' in plan view (e.g., the first, second, and third voltage connection lines ECLa, ECLb, and ECLc may have a mesh shape in plan view). However, one or more embodiments of the present disclosure are not limited thereto.

The first, second, and third voltage connection lines ECLa, ECLb, and ECLc may have substantially the same or similar planar shape. Because the first, second, and third voltage connection lines ECLa, ECLb, and ECLc have a mesh shape, the load of the first, second, and third voltage connection lines ECLa, ECLb, and ECLc and the second direct current voltage line ELVDL2′ may be reduced or minimized.

The second direct current voltage line ELVDL2′ may receive a direct current voltage. For example, the direct current voltage may be a first power voltage (e.g., the first power voltage ELVDD of FIG. 3). Alternatively, the direct current voltage may be an initialization voltage (e.g., the initialization voltage VINT of FIG. 3). In this case, the second direct current voltage line ELVDL2′ and the first, second, and third voltage connection lines ECLa, ECLb, and ECLc may be electrically connected to the initialization line VIL of FIG. 8.

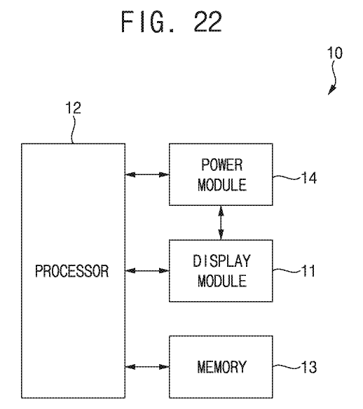

FIG. 22 is a block diagram illustrating an electronic device according to one or more embodiments of the present disclosure.

Referring to FIG. 22, an electronic device 10 according to one or more embodiments of the present disclosure may include a display 11, a processor 12, a memory 13, and a power supply 14.

A display device (e.g., the display device 100 of FIG. 1) according to one or more embodiments of the present disclosure may be applied to suitable electronic devices. The electronic device 10 may include the display device described above, and may further include a module or device having additional functions in addition to the display device.

The processor 12 may include at least one of a central processing unit (CPU) (e.g., a central processor or a central processing circuit), an application processor (AP), a graphic processing unit (GPU) (e.g., a graphic processor or a graphic processing circuit), a communication processor (CP), and/or an image signal processor (ISP).

The memory 13 may store data information suitable for the operation of the processor 12 or the display 11. In case that the processor 12 executes the application stored in the memory 13, an input image data (e.g., the input image data IDAT of FIG. 2) and/or a control signal (e.g., the control signal CTRL of FIG. 2) may be transmitted to the display 11, and the display 11 may process the received signal and output image information through a display screen.

The power supply 14 may include a power supply device such as a power adapter or a battery device, and a power conversion device, which may convert an external power supplied by the power supply device to generate power suitable for the operation of the electronic device 10.

At least one of each component of the electronic device 10 described above may be included in the display device according to one or more embodiments of the present disclosure. In addition, some of the individual devices functionally included in one device may be included in the display device, and other portions may be provided separately from the display device. For example, the display device may include the display 11, and the processor 12, the memory 13, and the power supply 14 may be provided in the form of other devices within the electronic device 10 other than the display device.

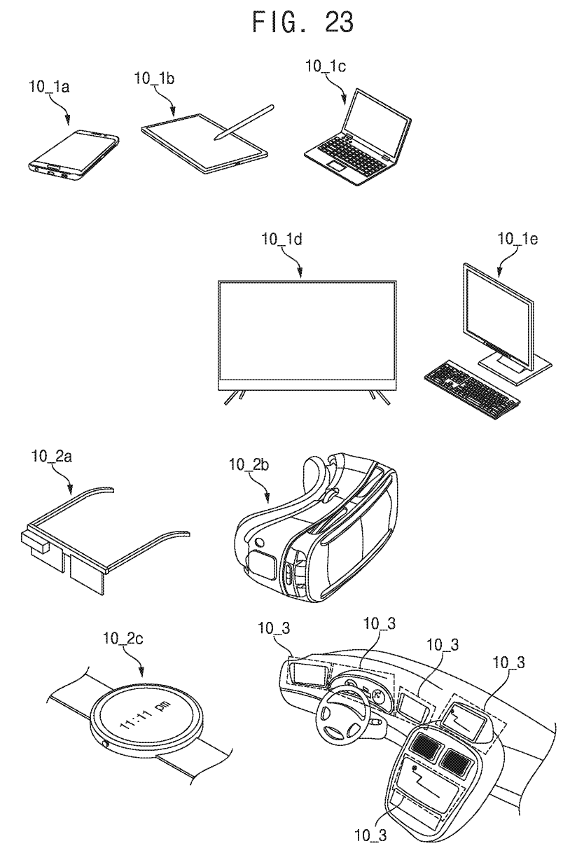

FIG. 23 is a schematic diagram illustrating an electronic device according to one or more suitable embodiments.

Referring to FIGS. 22 and 23, suitable electronic devices 10 to which display devices according to one or more embodiments of the present disclosure may be applied may include not only image display electronic devices such as a smartphone 10_1a, a tablet PC 10_1b, a laptop 10_1c, a TV 10_1d, and/or a desktop monitor 10_1e, but also wearable electronic devices including display devices, such as smart glasses 10_2a, a head-mounted display 10_2b, and a smart watch 10_2c, automotive electronic devices 10_3 including display devices, such as a dashboard of a car, a center fascia, a Center Information Display (CID) arranged on a dashboard, and a room mirror display, or the like.

Overall, the configuration of the display device may improve the display quality and the durability of the display device. For example, the thickness of the data line of the display device and the thickness of the direct current voltage line may be greater than the thickness of the capacitor electrodes of the display device. Accordingly, a resistance of the data line may be reduced or minimized to improve the display quality. Furthermore, the microlenses of the display device may improve light extraction efficiency, and the encapsulation substrate of the display device may protect the display panel from moisture penetration or gas inflow, thereby improving the durability of the display device.

As described above, while the present disclosure has been explained with reference to one or more embodiments, it will be understood by those of ordinary skill in the art upon reviewing the present disclosure that suitable modifications and changes may be made thereto without departing from the spirit and scope of the present disclosure as defined in the following claims.

The present disclosure may be applied to suitable display device, which may be equipped with a display device. For example, the present disclosure may be applied to high-resolution smartphones, mobile phones, smart pads, smart watches, tablet PCs, vehicle navigation systems, televisions, computer monitors, and/or notebook computers.

In the context of the present disclosure and unless otherwise defined, the terms "use/utilize," "using/utilizing," and "used/utilized" may be considered synonymous with the terms "utilize," "utilizing," and "utilized," respectively.

A person of ordinary skill in the art would appreciate, in view of the present disclosure in its entirety, that each suitable feature of the one or more suitable embodiments of the present disclosure may be combined or combined with each other (or one another), partially or entirely, and may be technically interlocked and operated in one or more suitable ways, and each embodiment may be implemented independently of each other (or one another) or in conjunction with each other (or one another) in any suitable manner unless otherwise stated or implied.

The display apparatus/device, the electronic apparatus/device, the manufacturing apparatuses thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be included on one integrated circuit (IC) chip or on separate IC chips. Further, the various components of the device may be implemented on a flexible printed circuit film, a tape carrier package (TCP), a printed circuit board (PCB), or included on one substrate. Further, the various components of the device may be a process or thread, running on one or more processors, in one or more computing devices, executing computer program instructions and interacting with other system components for performing the various functionalities described herein. The computer program instructions are stored in a memory, which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

While the present disclosure has been described with reference to one or more embodiments thereof, it will be apparent to those of ordinary skill in the art that one or more suitable changes and modifications may be made thereto without departing from the spirit and scope of the present disclosure as set forth in the following claims and equivalents thereof. Moreover, it shall be appreciated that the one or more embodiments of the present disclosure are not intended to restrict the present disclosure thereto and that every technical idea within the appended claims and their equivalents is interpreted to be included in the scope of the present disclosure and equivalents thereof.

What is claimed is:

1. A display device comprising:
a substate comprising an active portion;
a driving transistor comprising the active portion and a gate electrode above the substrate and overlapping a channel region of the active portion in plan view;
a capacitor comprising capacitor electrodes sequentially arranged above the gate electrode in a direction away from the substrate;
a data line above the capacitor electrodes and configured to receive a data voltage;
a direct current voltage line between the capacitor electrodes and the data line, configured to receive a direct current voltage, and overlapping the data line in plan view; and
a light-emitting layer above the data line.

2. The display device of claim 1, wherein a portion of the data line overlapping the capacitor electrodes is covered by the direct current voltage line.

3. The display device of claim 1, wherein a width of the direct current voltage line is substantially equal to or greater than a width of the data line.

4. The display device of claim 1, wherein a thickness of the direct current voltage line and a thickness of the data line are greater than respective thicknesses of the capacitor electrodes.

5. The display device of claim 1, wherein the direct current voltage comprises a power voltage.

6. The display device of claim 1, further comprising:
a voltage connection electrode under the direct current voltage line and coupled to the direct current voltage line through a first contact hole; and
a data connection electrode under the data line and coupled to the data line through a second contact hole,
wherein the data line comprises a first portion coupled to the data connection electrode and extending in a first direction and a second portion extending in a second direction crossing the first direction and covering the voltage connection electrode.

7. The display device of claim 1, further comprising:
a first pixel connection electrode in a same layer as the direct current voltage line;
a second pixel connection electrode in a same layer as the data line and coupled to the first pixel connection electrode through a contact hole; and
a pixel electrode above the second pixel connection electrode, electrically coupled to the second pixel connection electrode, and below the light-emitting layer.

8. The display device of claim 1, wherein the capacitor electrodes comprise:
a first-first capacitor electrode and a first-second capacitor electrode above the gate electrode;
a second-first capacitor electrode and a second-second capacitor electrode respectively above the first-first capacitor electrode and the first-second capacitor electrode;
a third-first capacitor electrode and a third-second capacitor electrode respectively above the second-first capacitor electrode and the second-second capacitor electrode; and
a fourth-first capacitor electrode and a fourth-second capacitor electrode respectively above the third-first capacitor electrode and the third-second capacitor electrode.

9. The display device of claim 8, wherein the first-first capacitor electrode, the second-first capacitor electrode, the third-first capacitor electrode, and the fourth-first capacitor electrode are coupled to each other through third contact holes,
wherein the first-second capacitor electrode, the second-second capacitor electrode, the third-second capacitor electrode, and the fourth-second capacitor electrode are coupled to each other through fourth contact holes,
wherein the first-first capacitor electrode is electrically coupled to a source region of the active portion, and
wherein the first-second capacitor electrode is electrically coupled to the gate electrode.

10. The display device of claim 9, wherein the first-first capacitor electrode, the second-second capacitor electrode, the third-first capacitor electrode, and the fourth-second capacitor electrode overlap each other in plan view, and
wherein the first-second capacitor electrode, the second-first capacitor electrode, the third-second capacitor electrode, and the fourth-first capacitor electrode overlap each other in plan view.

11. The display device of claim 9, wherein the first-first capacitor electrode, the second-first capacitor electrode, the third-first capacitor electrode, and the fourth-first capacitor electrode overlap each other in plan view, and
wherein the first-second capacitor electrode, the second-second capacitor electrode, the third-second capacitor electrode, and the fourth-second capacitor electrode overlap each other in plan view.

12. The display device of claim 1, wherein the capacitor electrodes comprise:
a first-first capacitor electrode and a first-second capacitor electrode above the gate electrode;
a second-first capacitor electrode and a second-second capacitor electrode respectively above the first-first capacitor electrode and the first-second capacitor electrode; and
a third-first capacitor electrode and a third-second capacitor electrode respectively above the second-first capacitor electrode and the second-second capacitor electrode,
wherein the first-first capacitor electrode, the second-first capacitor electrode, and the third-first capacitor electrode are coupled to each other through third contact holes,
wherein the first-second capacitor electrode, the second-second capacitor electrode, and the third-second capacitor electrode are coupled to each other through fourth contact holes,
wherein the first-first capacitor electrode is electrically coupled to a source region of the active portion, and
wherein the first-second capacitor electrode is electrically coupled to the gate electrode.

13. The display device of claim 12, wherein a thickness of the data line is greater than a thickness of the direct current voltage line.

14. The display device of claim 12, further comprising a voltage connection line under the direct current voltage line, coupled to the direct current voltage line through a contact hole, and surrounding the capacitor in plan view.

15. An electronic device comprising:
a display device comprising:
a silicon wafer substate comprising an active portion;
a driving transistor comprising the active portion and a gate electrode above the silicon wafer substrate and overlapping a channel region of the active portion in plan view;
a capacitor comprising capacitor electrodes sequentially arranged above the gate electrode in a direction away from the silicon wafer substrate;
a data line above the capacitor electrodes and configured to receive a data voltage;
a direct current voltage line between the capacitor electrodes and the data line, configured to receive a direct current voltage, and overlapping the data line in plan view; and
a light-emitting layer above the data line; and
a processor configured to provide an input image date and a control signal to the display device to control the display device.

16. The electronic device of claim 15, wherein a portion of the data line overlapping the capacitor electrodes is covered by the direct current voltage line.

17. The electronic device of claim 15, wherein a width of the direct current voltage line is substantially equal to or greater than a width of the data line.

18. The electronic device of claim 15, wherein a thickness of the direct current voltage line and a thickness of the data line are greater than respective thicknesses of the capacitor electrodes.

19. The electronic device of claim 15, wherein the display device further comprises:
a first pixel connection electrode in a same layer as the direct current voltage line;
a second pixel connection electrode in a same layer as the data line and coupled to the first pixel connection electrode through a contact hole; and
a pixel electrode above the second pixel connection electrode and electrically coupled to the second pixel connection electrode,
wherein the light-emitting layer is above the pixel electrode.

20. The electronic device of claim 15, wherein the capacitor electrodes comprise:
a first-first capacitor electrode and a first-second capacitor electrode above the gate electrode;
a second-first capacitor electrode and a second-second capacitor electrode respectively above the first-first capacitor electrode and the first-second capacitor electrode;
a third-first capacitor electrode and a third-second capacitor electrode respectively above the second-first capacitor electrode and the second-second capacitor electrode; and
a fourth-first capacitor electrode and a fourth-second capacitor electrode respectively above the third-first capacitor electrode and the third-second capacitor electrode,
wherein the first-first capacitor electrode, the second-first capacitor electrode, the third-first capacitor electrode, and the fourth-first capacitor electrode are coupled to each other through third contact holes,
wherein the first-second capacitor electrode, the second-second capacitor electrode, the third-second capacitor electrode, and the fourth-second capacitor electrode are coupled to each other through fourth contact holes,
wherein the first-first capacitor electrode is electrically coupled to a source region of the active portion, and
wherein the first-second capacitor electrode is electrically coupled to the gate electrode.
